(19) United States
(12) Patent Application Publication
(10) Pub. No.: US 2026/0123361 A1
(43) Pub. Date: Apr. 30, 2026

(54) APPARATUS FOR MANUFACTURING ELECTRONIC APPARATUS INCLUDING DISPLAY PANEL AND METHOD FOR MANUFACTURING THE ELECTRONIC APPARATUS

(71) Applicant: Samsung Display Co., LTD., Yongin-si (KR)

(72) Inventors: Kyungin Kim, Yongin-si (KR); Jungkook Jang, Yongin-si (KR); Jaeho Kim, 1, Samsung-ro (KR); Yonghun Choi, Yongin-si (KR)

(21) Appl. No.: 19/263,832

(22) Filed: Jul. 9, 2025

(30) Foreign Application Priority Data
Oct. 29, 2024 (KR) 10-2024-0149991

(51) Int. Cl. H01L 21/66; G01H 17/00; G09G 3/3233; H01L 21/677; H10K 59/12; H10K 71/70

(52) U.S. Cl. CPC H10P 74/27; G01H 17/00; H10K 59/1201; H10K 71/70; H10P 72/3208; G09G 3/3233; G09G 2300/0819; G09G 2300/0842; G09G 2300/0861

(57) ABSTRACT

A electronic apparatus manufacturing apparatus includes at least two transporters transporting process products, a processor performing a manufacturing process on a process product transported by at least one of the at least two transporters, a processor measurer disposed on the processor to measure a processor vibration of the processor, and a controller calculating a processor frequency response of the processor based on the processor vibration and adjusting a velocity and a position of each transporter and/or a number of transporters arranged in one area among the at least two transporters based on the processor frequency response.

This application claims priority to Korean Patent Application No. 10-2024-0149991, filed on Oct. 29, 2024, and all the benefits accruing therefrom under 35 U.S.C. § 119, the content of which in its entirety is herein incorporated by reference.

### BACKGROUND

### 1. Field

Embodiments relate to an apparatus and a method, and more particularly, to an electronic apparatus manufacturing apparatus and the electronic apparatus manufacturing method.

### 2. Description of the Related Art

Mobility-based electronic apparatuses are being widely used. In addition to small electronic apparatuses such as mobile phones, tablet personal computers (“PC”) are recently being widely used as mobile electronic apparatuses.

Such mobile electronic apparatuses include a display panel to provide visual information such as images or videos to a user in order to support various functions. Recently, as other parts for driving a display apparatus have been miniaturized, the proportion of a display panel in an electronic apparatus is increasing gradually and a structure capable of being bent from a flat state by a predetermined angle is also being developed.

### SUMMARY

In general, a distribution system providing various process products and/or parts between various devices may be arranged to manufacture an electronic apparatus. In this case, the process products and/or parts may be moved through an autonomous mobile robot or an automated guided vehicle in the distribution system. In this case, when the autonomous mobile robot or the automated guided vehicle operates in the process of moving the process products and/or parts, vibrations may be generated to affect an apparatus performing the electronic apparatus manufacturing process, thus causing a malfunction or failure of the apparatus performing a display apparatus manufacturing process. In order to overcome this limitation, it may be desired to accurately control the operation of the autonomous mobile robot or the automated guided vehicle. Embodiments include an electronic apparatus manufacturing apparatus and the electronic apparatus manufacturing method that may control the operation of the autonomous mobile robot or the automated guided vehicle according to the vibrations.

Additional features will be set forth in part in the description which follows and, in part, will be apparent from the description, or may be learned by practice of the presented embodiments of the disclosure.

In an embodiment, an electronic apparatus manufacturing apparatus includes at least two transporters transporting process products, a processor performing a manufacturing process on a process product transported by at least one of the at least two transporters, a processor measurer disposed on the processor to measure a processor vibration of the processor, and a controller calculating a processor frequency response of the processor based on the processor vibration and adjusting a velocity and a position of each transporter and/or a number of transporters arranged in one area among the at least two transporters based on the processor frequency response.

In an embodiment, the controller may reduce a velocity of at least one of the at least two transporters when the processor frequency response is determined to be greater than a preset frequency response.

In an embodiment, the controller may reduce a velocity of a transporter with a highest velocity among the at least two transporters before a velocity of other transporters among the at least two transporters when the processor frequency response is greater than a preset frequency response.

In an embodiment, the controller may increase a velocity of at least one of the at least two transporters when the processor frequency response is determined to be less than a preset frequency response.

In an embodiment, the controller may change a path of at least one of the at least two transporters into a path different from an existing path when the processor frequency response is greater than a preset frequency response.

In an embodiment, the controller may determine a process schedule including a velocity and a movement path of the at least two transporters based on a transporter vibration and the processor vibration measured by the processor measurer while one of the at least two transporters moves.

In an embodiment, the electronic apparatus manufacturing apparatus may further include a transporter measurer disposed on each transporter to measure a transporter vibration of the transporter, where the controller may calculate a transporter frequency response of each transporter based on the transporter vibration and calculate an impulse response of the processor according to the transporter vibration of one of the at least two transporters based on the transporter frequency response and the processor frequency response.

In an embodiment, the controller may control a velocity of at least one of the at least two transporters based on the impulse response.

In an embodiment, an electronic apparatus manufacturing method includes measuring a processor vibration of a processor that occurs in the processor when at least two transporters move, calculating a processor frequency response based on the processor vibration, and adjusting a velocity and a position of each transporter and/or a number of transporters arranged in one area among the at least two transporters based on the processor frequency response.

In an embodiment, the electronic apparatus manufacturing method may further include comparing the processor frequency response with a preset frequency response.

In an embodiment, the electronic apparatus manufacturing method may further include reducing a velocity of at least one of the at least two transporters when the processor frequency response is determined to be greater than the preset frequency response.

In an embodiment, the electronic apparatus manufacturing method may further include reducing a velocity of a transporter with a highest velocity among the at least two transporters before a velocity of remaining (the other) transporters among the at least two transporters when the processor frequency response is greater than the preset frequency response.

In an embodiment, the electronic apparatus manufacturing method may further include increasing a velocity of at least one of the at least two transporters when the processor frequency response is determined to be less than the preset frequency response.

In an embodiment, the electronic apparatus manufacturing method may further include changing a path of at least one of the at least two transporters into a path different from an existing path when the processor frequency response is greater than or equal to the preset frequency response.

In an embodiment, the electronic apparatus manufacturing method may further include measuring a transporter vibration of the transporter that occurs according to a movement of the at least two transporters.

In an embodiment, the electronic apparatus manufacturing method may further include determining a process schedule including a velocity and a movement path of the at least two transporters based on the transporter vibration and the processor vibration while one of the at least two transporters moves.

In an embodiment, the electronic apparatus manufacturing method may further include calculating a transporter frequency response of each transporter based on the transporter vibration.

In an embodiment, the electronic apparatus manufacturing method may further include calculating an impulse response of the processor according to the transporter vibration of one of the at least two transporters based on the transporter frequency response and the processor frequency response.

In an embodiment, a velocity of one of the at least two transporters may be controlled based on the impulse response.

In an embodiment, a velocity of one of the at least two transporters with a greatest impulse response of the processor according to the transporter vibration may be more variable than a velocity of remaining (the other) transporters among the at least two transporters.

Other features and advantages other than those described above will be apparent from the accompanying drawings, the attached claims, and the detailed description of the disclosure.

These general and particular features may be implemented by systems, methods, computer programs, or any combinations of systems, methods, and computer programs.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a perspective view schematically illustrating an electronic apparatus manufacturing apparatus;

FIG. 2 is a block diagram schematically illustrating a controller of an electronic apparatus manufacturing apparatus;

FIGS. 3A and 3B are flowcharts schematically illustrating a control flow of the electronic apparatus manufacturing apparatus illustrated in FIGS. 1 and 2;

FIG. 4 is a perspective view schematically illustrating an electronic apparatus;

FIG. 5 is an exploded perspective view schematically illustrating the electronic apparatus of FIG. 4;

FIG. 6 is a block diagram schematically illustrating the electronic apparatus of FIG. 4;

FIG. 7 is a plan view schematically illustrating a portion of the electronic apparatus;

FIG. 8 is a side view schematically illustrating a portion of the electronic apparatus illustrated in FIG. 7;

FIG. 9 is a plan view schematically illustrating a portion of the electronic apparatus illustrated in FIG. 7;

FIG. 10 is an equivalent circuit diagram of a pixel disposed in a display area of a display panel illustrated in FIG. 9; and

FIG. 11 is a cross-sectional view schematically illustrating a portion of the display panel illustrated in FIG. 9.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and particular embodiments thereof are illustrated in the drawings and will be described herein in detail. The effects and features of the disclosure and methods of achieving them will become apparent with reference to the embodiments described below in detail together with the drawings. However, the disclosure is not limited to the embodiments described below and may be implemented in various forms.

Hereinafter, embodiments will be described in detail with reference to the accompanying drawings, and in the following description, like reference numerals will denote like elements and redundant descriptions thereof will be omitted for conciseness.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

It will be understood that terms such as “comprise,” “include,” and “have” used herein specify the presence of stated features or elements, but do not preclude the presence or addition of one or more other features or elements.

It will be understood that when a layer, region, or component is referred to as being “on” another layer, region, or component, it may be “directly on” the other layer, region, or component or may be “indirectly on” the other layer, region, or component with one or more intervening layers, regions, or components therebetween.

The terms such as “unit” “module” “processor,” “controller” and “measurer” as used herein are intended to mean a hardware component such as a circuitry that performs a predetermined function. The hardware component may include a field-programmable gate array (“FPGA”) or an application-specific integrated circuit (“ASIC”), for example.

Sizes of components in the drawings may be exaggerated for convenience of description. In other words, because the sizes and shapes of components in the drawings are arbitrarily illustrated for convenience of description, the disclosure is not limited thereto.

Also, herein, the X axis, the Y axis, and the Z axis are not limited to three axes of the rectangular coordinate system and may be interpreted in a broader sense. For example, the X axis, the Y axis, and the X axis may be perpendicular to one another or may represent different directions that are not perpendicular to one another.

When an illustrative embodiment may be implemented differently, a particular process order may be performed differently from the described order. For example, two consecutively described processes may be performed substantially at the same time or performed in an order opposite to the described order.

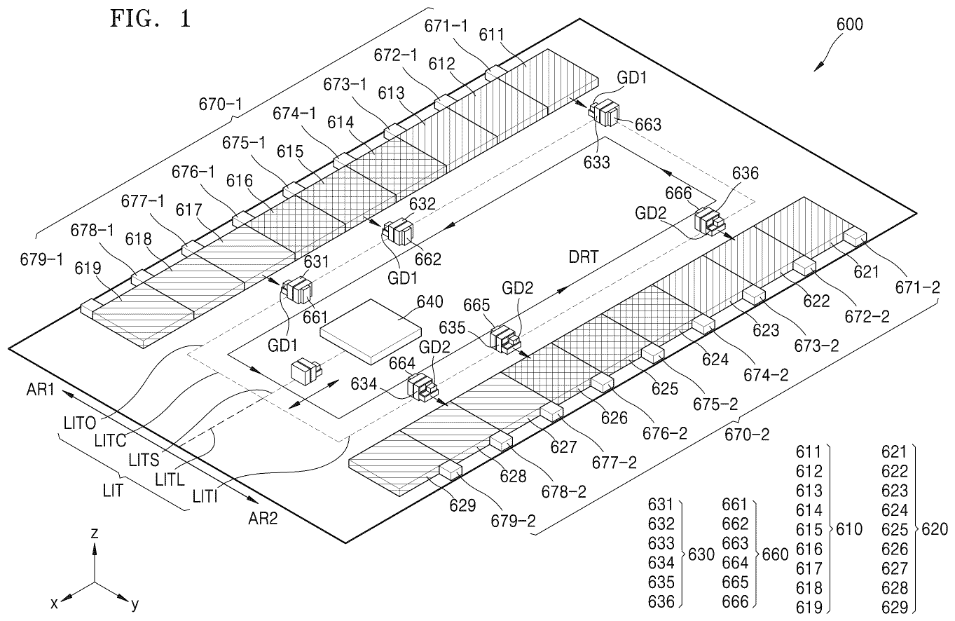

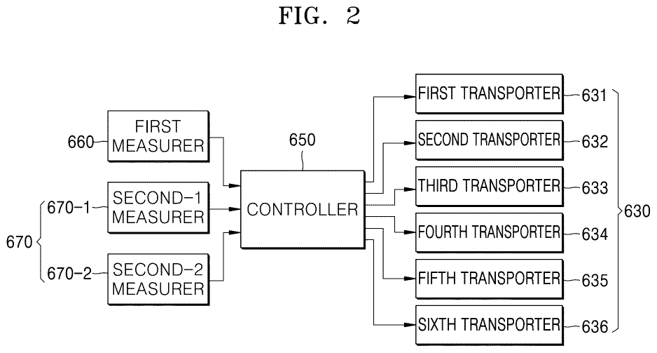

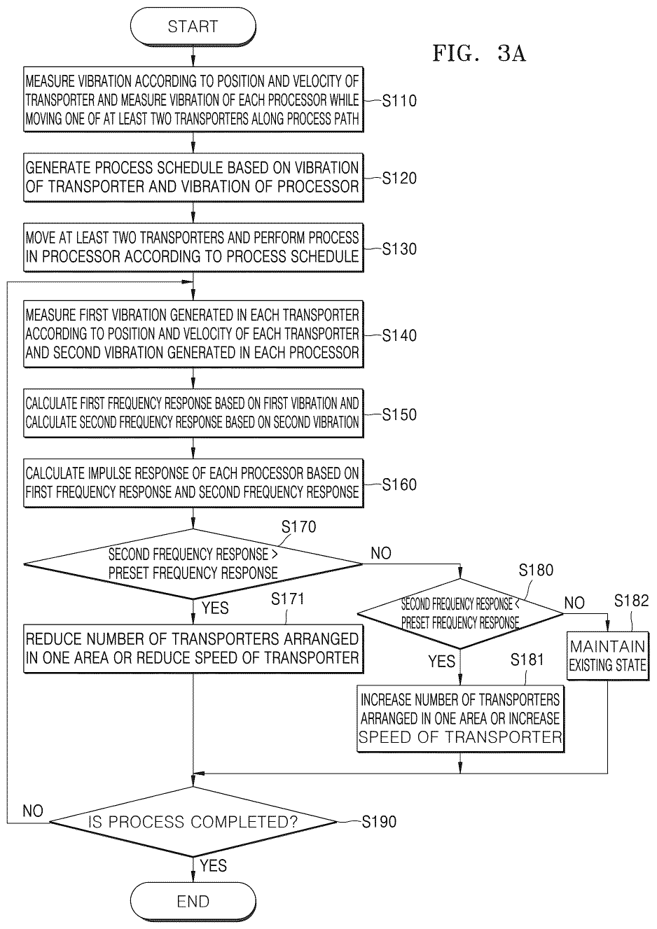

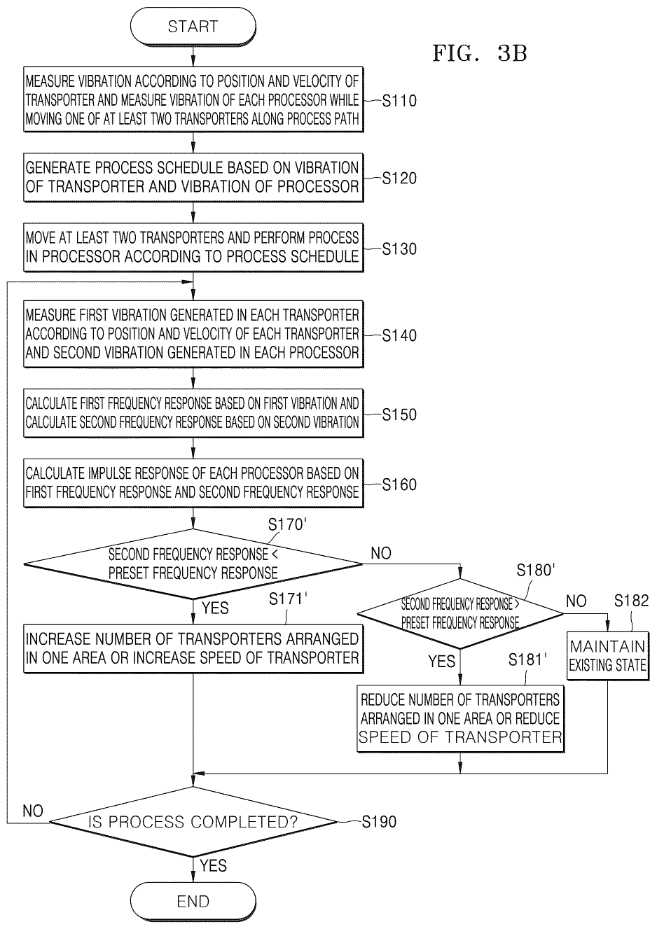

FIG. 1 is a perspective view schematically illustrating an embodiment of an apparatus (hereinafter also referred to as “an electronic apparatus manufacturing apparatus”) which manufactures an electronic apparatus including a display panel. FIG. 2 is a block diagram schematically illustrating an embodiment of a controller of an electronic apparatus manufacturing apparatus. FIGS. 3A and 3B are flowcharts schematically illustrating a control flow of the electronic apparatus manufacturing apparatus illustrated in FIGS. 1 and 2.

Referring to FIGS. 1 to 3B, an electronic apparatus manufacturing apparatus 600 may include a first process line 610, a second process line 620, a plurality of transporters 630, a storage unit 640, a controller 650, a first measurer 660, and a second measurer 670.

The first process line 610 may include a plurality of first processors (not illustrated). The plurality of first processors may be sequentially arranged in a first direction (e.g., an x-axis direction).

The plurality of first processors may primarily process a first processed product (or workpiece) GD1. In this case, each first processor may include a plurality of first parts. In an embodiment, the plurality of first parts may include various motors, frames, guides, and/or various sensors, for example.

The plurality of first processors may include a first-1 processor 611, a first-2 processor 612, . . . , a first-P processor (not illustrated). Here, P may be a natural number greater than or equal to 0. Hereinafter, for convenience of description, a case where the plurality of first processors include a first-1 processor 611, a first-2 processor 612, a first-3 processor 613, a first-4 processor 614, a first-5 processor 615, a first-6 processor 616, a first-7 processor 617, a first-8 processor 618, and a first-9 processor 619 will be mainly described in detail.

Each of the plurality of first processors may be in any one of a run state, an idle state, and a down state. The run state may be a state in which the first processed product GD1 may be processed. The idle state may be a state in which the processor may not be temporarily run due to a temporary error, for example. The down state may be a state in which the processor may not be continuously run.

The second process line 620 may be disposed apart from the first process line 610 in a second direction (e.g., a y-axis direction) intersecting the first direction (e.g., the x-axis direction). The second process line 620 may include a plurality of second processors (not illustrated). The plurality of second processors may be sequentially arranged in the first direction (e.g., the x-axis direction).

Each second processor may manufacture a second processed product GD2 by secondarily processing the first processed product GD1. In this case, the second processed product GD2 may be a final product or an intermediate product for producing a final product. In this case, the first processed product GD1 and the second processed product GD2 may be components for manufacturing an electronic apparatus. In an embodiment, the first processed product GD1 or the second processed product GD2 may include a portion of a display panel, a display panel, a data driver, a display circuit board, at least one of wireless communicators, at least one of input units, a sensor unit, at least one of output units, an interface unit, a memory, and/or a power supply unit, which will be described below, for example.

The plurality of second processors may include a second-1 processor 621, a second-2 processor 622, . . . , a second-Q processor (not illustrated). Here, Q may be a natural number greater than or equal to 1. Hereinafter, for convenience of description, a case where the plurality of second processors include a second-1 processor 621, a second-2 processor 622, a second-3 processor 623, a second-4 processor 624, a second-5 processor 625, a second-6 processor 626, a second-7 processor 627, a second-8 processor 628, and a second-9 processor 629 will be mainly described in detail.

Each of the plurality of second processors may be in any one of a run state, an idle state, and a down state. The run state may be a state in which a second processed product GD2 may be processed. The idle state may be a state in which the processor may not be temporarily run due to a temporary error, for example. The down state may be a state in which the processor may not be continuously run.

The storage unit 640 may be disposed between the first process line 610 and the second process line 620 and may store a first processed product GD1. That is, the first processed product GD1 processed in at least one of the plurality of first processors may be input to the storage unit 640 or output from the storage unit 640.

The transporter 630 may move along a transport path LIT defined between the first process line 610 and the second process line 620 and may be provided as a plurality of transporters 630. The plurality of transporters 630 may transport the first processed product GD1 from the first process line 610 to the second process line 620 or the storage unit 640. The plurality of transporters 630 may output the first processed product GD1 from the first process line 610, transport the same to the second process line 620, and then input the same to the second process line 620.

The transporter 630 described above may move along a given path according to a preset schedule. In this case, the transporter 630 may be an autonomous mobile robot or an automated guided vehicle. Hereinafter, for convenience of description, a case where the transporter 630 is an automated guided vehicle will be mainly described in detail.

The plurality of transporters 630 may include a first transporter 631, a second transporter 632, a third transporter 633, a fourth transporter 634, a fifth transporter 635, and a sixth transporter 636 that transport the first processed product GD1 or the second processed product GD2 to at least one of the first process line 610 and the second process line 620. In this case, the number of transporters 630 is not limited thereto and may be at least two.

The plurality of transporters 630 may circulate in a transport direction DRT while moving along the transport path LIT. A plurality of transport paths LIT may include an output path LITO, an input path LITI, a connection path LITC, a storage path LITS, and an avoidance path LITL. In this case, each of the plurality of transport paths LIT may refer to a separate structure disposed on the inner wall or outer wall of a building, the ground, or the like or a path along which each transporter 630 moves without a separate structure.

The output path LITO may be a path through which the plurality of transporters 630 output the first processed product GD1 from the first process line 610. In an embodiment, the output path LITO may extend in the first direction (e.g., the x-axis direction) parallel to the first process line 610 and may be defined next (adjacent) to the first process line 610, for example. While moving in the transport direction DRT along the output path LITO, the plurality of transporters 630 may stop next (adjacent) to any one of the plurality of first processors and then output any one of the first processed products GD1.

The input path LITI may be a path through which the plurality of transporters 630 input the first processed product GD1 to the second process line 620. In an embodiment, the input path LITI may extend in the first direction (e.g., the x-axis direction) parallel to the second process line 620 and may be defined next (adjacent) to the second process line 620, for example. While moving in the transport direction DRT along the input path LITI, the plurality of transporters 630 may stop next (adjacent) to any one of the plurality of second processors and then input any one of the first processed products GD1 to one of the plurality of second processors.

The connection path LITC may connect the output path LITO and the input path LITI to each other. The connection path LITC may be provided as two connection paths. The connection path LITC may extend in the second direction (e.g., the y-axis direction), and opposite ends of the connection path LITC may be respectively connected to the end of the output path LITO and the end of the input path LITI. The plurality of transporters 630 may circulate along the output path LITO, the connection path LITC, the input path LITI, and the connection path LITC in the transport direction DRT.

In this structure, the planar shape of the transport path LIT may be tetragonal. Also, the transport direction DRT may be a counterclockwise direction when viewed from the top (e.g., a direction rotating around the +Z axis). However, this is only an illustrative embodiment, and the transport path LIT and the transport direction DRT are not limited thereto.

The storage path LITS may be a path through which the plurality of transporters 630 input the first processed product GD1 to the storage unit 640. The storage path LITS may be connected to the connection path LITC. The plurality of transporters 630 may output any one of the plurality of first processed products GD1 from the first process line 610 and then stop next (adjacent) to the storage unit 640 while moving sequentially along the output path LITO, the connection path LITC, and the storage path LITS and then input any one of the plurality of first processed products GD1 to the storage unit 640 and then move sequentially along the storage path LITS, the connection path LITC, and the input path LITI.

The avoidance path LITL may guide at least one of the plurality of transporters 630 to another electronic apparatus manufacturing apparatus or guide an avoidance space according to the determination of the controller 650. In this case, the avoidance path LITL may be defined in an area where a vibration does not occur in a plurality of processors or a vibration occurring in a plurality of processors is slight according to the movement of the transporter 630 arranged on the avoidance path LITL.

In the electronic apparatus manufacturing apparatus 600, a space in which a plurality of processors are arranged may be divided into a plurality of areas. In an embodiment, the space may be divided into a first area AR1 in which a first processor is disposed and a second area AR2 in which a second processor is disposed, for example. The first area AR1 and the second area AR2 may be defined as an area in which the vibration of the processor generated according to the movement of at least one transporter 630 is less than a predetermined value when at least one transporter 630 moves. In an embodiment, when at least one transporter 630 moves in the first area AR1, the transporter 630 moving in the first area AR1 may not be a major factor in the generation of the vibration of a plurality of second processors arranged in the second area AR2, for example. Also, when at least one transporter 630 moves in the second area AR2, the transporter 630 moving in the second area AR2 may not be a major factor in the generation of the vibration of a plurality of first processors arranged in the first area AR1. Hereinafter, for the convenience of description, a case where the first area AR1 is an area from the storage unit 640 to a portion where a plurality of first processors are disposed and the second area AR2 is an area from the storage unit 640 to a portion where a plurality of second processors are disposed will be mainly described in detail.

The controller 650 may control the electronic apparatus manufacturing apparatus 600 by calculating various information based on the results measured by the first measurer 660 that is a transporter measurer and the second measurer 670 that is a processor measurer. In this case, the controller 650 may be disposed inside or outside the electronic apparatus manufacturing apparatus 600 and may be connected by wireless or by wire to each component of the electronic apparatus manufacturing apparatus 600.

The first measurer 660 may be disposed on one transporter 630 to measure a first vibration that is a transporter vibration generated in the transporter 630 when the transporter 630 moves. In this case, the first measurer 660 may include a vibration sensor that measures at least one of speed, acceleration, and amplitude. Hereinafter, for convenience of description, a case where the first measurer 660 measures the amplitude of the first vibration when the transporter 630 vibrates will be mainly described in detail.

The first measurer 660 may be provided as a plurality of first measurers 660. The plurality of first measurers 660 may include a first-1 measurer 661 disposed in the first transporter 631, a first-2 measurer 662 disposed in the second transporter 632, a first-3 measurer 663 disposed in the third transporter 633, a first-4 measurer 664 disposed in the fourth transporter 634, a first-5 measurer 665 disposed in the fifth transporter 635, and a first-6 measurer 666 disposed in the sixth transporter 636. The first measurer 660 described above may detect a vibration occurring in each transporter 630 when each transporter 630 moves. In this case, the first measurer 660 may transmit the measured vibration to the controller 650.

The second measurer 670 may be disposed in the first process line 610 and the second process line 620. In this case, the second measurer 670 may measure a second vibration that is a processor vibration of the entirety of the electronic apparatus manufacturing apparatus 600, the entirety of the first process line 610, the entirety of the second process line 620, or each processor (e.g., each first processor and each second processor). In an embodiment, the second measurer 670 may be disposed in a portion of the electronic apparatus manufacturing apparatus 600 to measure the second vibration of the electronic apparatus manufacturing apparatus 600, for example. In another embodiment, the second measurer 670 may be disposed in each of the first process line 610 and the second process line 620 to measure the second vibration of each of the first process line 610 and the second process line 620. In another embodiment, the second measurer 670 may be separately disposed in each processor disposed in the first process line 610 and the second process line 620 to measure the second vibration of each processor. Hereinafter, for convenience of description, a case where the second measurer 670 is provided as a plurality of second measurers 670 and each second measurer 670 is separately arranged in each processor will be mainly described in detail.

The second measurer 670 may include a second-1 measurer 670-1 disposed in the first process line 610 and a second-2 measurer 670-2 disposed in the second process line 620. In this case, the second-1 measurer 670-1 may include a first-1 device measurer 671-1, a first-2 device measurer 672-1, a first-3 device measurer 673-1, a first-4 device measurer 674-1, a first-5 device measurer 675-1, a first-6 device measurer 676-1, a first-7 device measurer 677-1, a first-8 device measurer 678-1, and a first-9 device measurer 679-1 that are respectively arranged in the first-1 processor 611, the first-2 processor 612, the first-3 processor 613, the first-4 processor 614, the first-5 processor 615, the first-6 processor 616, the first-7 processor 617, the first-8 processor 618, and the first-9 processor 619. Also, the second-2 measurer 670-2 may include a second-1 device measurer 671-2, a second-2 device measurer 672-2, a second-3 device measurer 673-2, a second-4 device measurer 674-2, a second-5 device measurer 675-2, a second-6 device measurer 676-2, a second-7 device measurer 677-2, a second-8 device measurer 678-2, and a second-9 device measurer 679-2 that are respectively arranged in the second-1 processor 621, the second-2 processor 622, the second-3 processor 623, the second-4 processor 624, the second-5 processor 625, the second-6 processor 626, the second-7 processor 627, the second-8 processor 628, and the second-9 processor 629.

Each of the first measurer 660 and the second measurer 670 described above may measure the vibration of corresponding transporter 630 and the vibration of corresponding processor and transmit the measured vibrations to the controller 650. In this case, FIG. 2 illustrates that the results measured by the first measurer 660, the second-1 measurer 670-1, and the second-2 measurer 670-2 are transmitted to the controller 650; however, the first measurer 660 illustrated in FIG. 2 may refer to each of the first-1 measurer 661, the first-2 measurer 662, the first-3 measurer 663, the first-4 measurer 664, the first-5 measurer 665, and the first-6 measurer 666. Also, the second-1 measurer 670-1 illustrated in FIG. 2 may refer to each of the first-1 device measurer 671-1, the first-2 device measurer 672-1, the first-3 device measurer 673-1, the first-4 device measurer 674-1, the first-5 device measurer 675-1, the first-6 device measurer 676-1, the first-7 device measurer 677-1, the first-8 device measurer 678-1, and the first-9 device measurer 679-1, and the second-2 measurer 670-2 may refer to each of the second-1 device measurer 671-2, the second-2 device measurer 672-2, the second-3 device measurer 673-2, the second-4 device measurer 674-2, the second-5 device measurer 675-2, the second-6 device measurer 676-2, the second-7 device measurer 677-2, the second-8 device measurer 678-2, and the second-9 device measurer 679-2.

Referring to FIG. 3A, as for the operation of the electronic apparatus manufacturing apparatus 600, the controller 650 may set a first schedule to be used in the process based on the results measured by the first measurer 660 and the second measurer 670. In this case, the controller 650 may set a first schedule based on the vibration measured by the first measurer 660 according to the variation in the position and velocity of the moving transporter 630 while moving one of the transporters 630 and the vibration generated in at least one processor. In an embodiment, the controller 650 may measure a vibration generated in the first-1 processor 611 according to the position, velocity, and vibration of the first transporter 631 while moving the first transporter 631 and then generate a first schedule through a preset program based on the measurement result thereof, for example. Hereinafter, for the convenience of description, a case where the moving transporter 630 is the first transporter 631 will be mainly described in detail.

When the first transporter 631 moves, the first measurer 660 may measure a first vibration generated in the first transporter 631 and transmit the first vibration to the controller 650. In this case, a second vibration may be generated in the processor due to the movement of the first transporter 631. In this case, the second measurer 670 may measure a second vibration generated in the processor and transmit the second vibration to the controller 650. The second vibration transmitted to the controller 650 may be at least one in number. In an embodiment, the second vibration may be a vibration generated in one of a plurality of processors, for example. In another embodiment, the second vibration may include a plurality of second vibrations, and the plurality of second vibrations may be vibrations respectively generated in at least two of the plurality of processors (S110).

The controller 650 may perform the above process a plurality of times by varying the velocity thereof. Based on the data obtained through this, the controller 650 may calculate a second vibration of each processor according to the position and velocity of the first transporter 631. Accordingly, the controller 650 may generate a first schedule that is a process schedule including information about the position and velocity of the transporter 630, the number of transporters 630 to be arranged in each area, or the like so that the vibration of each of the plurality of processors is optimized when the plurality of transporters 630 move (S120).

The electronic apparatus manufacturing apparatus 600 may perform an operation based on the first schedule. In this case, the first schedule may include the position and velocity of each transporter 630 depending on the process order, the process time, or the like, the number of transporters 630 arranged in a particular area, and whether the first process line 610 and the second process line 620 operate.

The controller 650 may control the operation of each of each transporter 630, the first process line 610, and the second process line 620 according to the first schedule (S130).

During the operation described above, the first vibration and the second vibration respectively measured by each of the first measurer 660 disposed in each transporter 630 and the second measurer 670 disposed in each processor may be transmitted to the controller 650 (S140).

Based on the first vibration, the controller 650 may calculate a first frequency response that is a transporter frequency response. In this case, the controller 650 may calculate a first frequency response of each transporter 630. Also, the controller 650 may calculate the first frequency response for each of the position and velocity of each transporter 630. In this case, the controller 650 may calculate a first frequency response of each transporter 630 moved when the corresponding transporter 630 reaches a second position at a predetermined distance from a first position instead of continuously calculating a first frequency response as the position of each transporter 630 varies. Accordingly, the controller 650 may calculate a first frequency response for each position and each velocity of each transporter 630. The controller 650 may calculate a second frequency response, which is a processor frequency response of each processor, based on the second vibration when the transporter 630 moves (S150).

The controller 650 may calculate an impulse response of each processor based on the first frequency response and the second frequency response described above. In this case, the impulse response may be calculated separately according to each transporter 630 and each processor by Equation 1 below, and the unit thereof may be in terms of decibel (dB).

$${H}_{m ( {x}_{i} , {y}_{j} , {v}_{mk} )} ( J ω ) = \frac{{E}_{n ( {x}_{i} , {y}_{j} , {v}_{mk} )} ( J ω )}{{A}_{m ( {x}_{i} , {y}_{j} , {v}_{mk} )} ( J ω )} \qquad [ Equation 1 ]$$

Here, “n” and “m” are natural numbers and may vary depending on the number of processors and the number of transporters 630. In an embodiment, referring to FIG. 1, “n” may be 1 in the case of the first-1 processor 611, 2 in the case of the first-2 processor 612, 3 in the case of the first-3 processor 613, 4 in the case of the first-4 processor 614, 5 in the case of the first-5 processor 615, 6 in the case of the first-6 processor 616, 7 in the case of the first-7 processor 617, 8 in the case of the first-8 processor 618, 9 in the case of the first-9 processor 619, 10 in the case of the second-1 processor 621, 11 in the case of the second-2 processor 622, 12 in the case of the second-3 processor 623, 13 in the case of the second-4 processor 624, 14 in the case of the second-5 processor 625, 15 in the case of the second-6 processor 626, 16 in the case of the second-7 processor 627, 17 in the case of the second-8 processor 628, and 18 in the case of the second-9 processor 629, for example. Also, “m” may be 1 in the case of the first transporter 631, 2 in the case of the second transporter 632, 3 in the case of the third transporter 633, 4 in the case of the fourth transporter 634, 5 in the case of the fifth transporter 635, and 6 in the case of the sixth transporter 636. Aₘ₍ₓ_{ᵢ}_{,y}_{ⱼ}_{,v}_{ₘₖ}₎(Jω) may denote a first frequency response when the velocity of the corresponding m-th transporter 630 is Vink at coordinates of (xᵢ,yⱼ), Eₙ₍ₓ_{ᵢ}_{,y}_{ⱼ}_{,v}_{ₘₖ}₎ (Jω) may denote a second frequency response of the processor corresponding to “n” when the velocity of the m-th transporter 630 is vₘₖ at coordinates of (xᵢ,yⱼ), and Hₘ₍ₓ_{ᵢ}_{,y}_{ⱼ}_{,v}_{ₖ}₎(Jω) may denote an impulse response representing the influence of the corresponding m-th transporter 630 on the vibration of the processor. Also, (xᵢ,yⱼ) may denote the coordinates of the corresponding m-th transporter 630, and vₘₖ may denote the velocity of the m-th transporter 630 at the corresponding coordinates. In this case, the unit of the first frequency response and the second frequency response may be dB. Also, the unit of the velocity may be in terms of meter per second (m/s) (S160).

The controller 650 may compare the second frequency response with a preset frequency response. In this case, when a plurality of second frequency responses are calculated, the controller 650 may compare the plurality of second frequency responses with the preset frequency response in various ways. In an embodiment, as one transporter 630 moves when generating the first schedule, the controller 650 may compare the second frequency response of the processor having the greatest value among the second vibrations generated in each processor with the preset frequency response, for example. In another embodiment, the controller 650 may calculate the second frequency response of each processor and then compare the average of the second frequency responses with the preset frequency response. In another embodiment, the controller 650 may select the second frequency response to be compared with the preset frequency response among the second frequency responses of the respective processors according to the importance. In an embodiment, the controller 650 may select a second frequency response of the processor that is most sensitive to the vibration and compare the selected second frequency response with the preset frequency response, for example. Hereinafter, for convenience of description, a case where the controller 650 compares the second frequency response of a processor with the preset frequency response will be mainly described in detail.

The controller 650 may determine whether the second frequency response of one processor is greater than the preset frequency response (S170).

When determining that the second frequency response of one processor is greater than the preset frequency response, the controller 650 may reduce the number of transporters 630 that are or will be arranged in one area. In an embodiment, when it is determined that the second frequency response of one processor is greater than the preset frequency response, the controller 650 may control at least one of the transporters 630 to move to the second area AR2, the storage unit 640, or the avoidance path LITL such that the number of transporters 630 arranged in the first area AR1 and/or the second area AR2 becomes smaller than that illustrated in FIG. 1, for example. In this case, at least one of at least two transporters 630 of the electronic apparatus manufacturing apparatus 600 may move along a path different from an existing path. In another embodiment, the controller 650 may not introduce the transporter 630 to be newly introduced into the first area AR1 and/or the second area AR2.

In an alternative embodiment, the controller 650 may reduce the velocity of each transporter 630 based on Equation 2 below (S171).

$${v}_{m k}^{′} = {v}_{m k} - {P}_{m k} \times \vert {E}_{n} ( J ω ) - {limit}_{n} ( Jω ) \vert \qquad [ Equation 2 ]$$

Here, “n” and Eₙ(Jω) may be the second frequency response of each processor at the time of measuring the second vibration. limitₙ(Jω) may be a preset frequency response that is an allowable value set by the controller 650 among the second frequency responses of the corresponding processor. Also, Vink may denote the current velocity of the corresponding transporter 630, and

$${v}_{m k}^{′}$$

may denote the velocity changed from the current velocity of the corresponding transporter 630.

Pₘₖ may denote a gain in PID control and may be calculated by Equation 3 below. In this case, Pₘₖ may be calculated separately for each transporter 630. Here, the unit of Pₘₖ may be meter per ‘second multiplied by decibel’ (m/sdB).

$${P}_{m k} = α \times {H}_{m} ( J ω ) \qquad [ Equation 3 ]$$

Here, a may be a constant and may be determined by the type of the electronic apparatus manufacturing apparatus 600, the type of the transporter, the type of the processor, and/or the like. In this case, a may be a state preset in the controller 650 and the unit thereof may be meter per ‘second multiplied by square decibel’ (m/sdB²). Also, in the case of Hₘ(Jω), it may be obtained similarly to Equation 1 as an impulse response of the corresponding processor by the corresponding transporter 630 and may be an impulse response of the corresponding processor by the corresponding transporter 630 at the time of measurement. In this case, the first measurer 660 and the second measurer 670 may not continuously monitor the first vibration and the second vibration respectively as the position of the transporter 630 varies. In this case, the impulse response of each processor at the position of the transporter 630 where the first vibration and the second vibration are not measured may be calculated by interpolation based on the first frequency response and the second frequency response at the position of the transporter 630 where the first vibration and the second vibration are measured.

In the case of reducing the velocity of the transporter 630, the controller 650 may reduce only the velocity of the transporter 630 with the highest velocity among the plurality of transporters 630. In another embodiment, as for the velocity of each of the plurality of transporters 630, the controller 650 may reduce the velocity of each transporter 630 by applying Equation 2 to each transporter 630. In this case, in the case of adjusting the velocity of the plurality of transporters 630, the velocity of the transporter 630 with the greatest impulse response among the plurality of transporters 630 may be reduced the most. In other words, because Pₘₖ of the transporter 630 with the greatest impulse response also increases, the amount of reducing the velocity of the corresponding transporter 630 may be greater than that of other transporters 630.

Moreover, when the second frequency response is not greater than the preset frequency response, the controller 650 may determine whether the second frequency response is less than the preset frequency response (S180).

When it is determined that the second frequency response is less than the preset frequency response, the controller 650 may increase the number of transporters 630 arranged in one area or increase the velocity of the transporter 630 through Equation 4 below. In this case, a method of increasing the number of transporters 630 may be performed by arranging one of the transporters 630 arranged in the first area AR1 or the second area AR2 in another area or by introducing a new transporter 630 into the first area AR1 and/or the second area AR2. In this case, at least one of at least two transporters 630 of the electronic apparatus manufacturing apparatus 600 may move along a path different from an existing path (S181).

$${v}_{mk}^{″} = MIN ( {v}_{m k} + {P}_{m k} \times \vert {limit}_{n} ( J ω ) - {E}_{n} ( J ω ) \vert , {v}_{MAX} ) \qquad [ Equation 4 ]$$

Here, “n” and Eₙ(Jω) may be the same as those described in Equation 1. limitₙ(Jω) may be a preset frequency response that is an allowable value set by the controller 650 among the second frequency responses of the corresponding processor. Also, vₘₖ may be a current velocity of the corresponding transporter 630, and

$${v}_{mk}^{″}$$

is a velocity to which the corresponding transporter 630 is changed from the current velocity. Pₘₖ may be calculated by Equation 3. v_{MAX} may be a maximum velocity that the corresponding transporter 630 may achieve and may be a value set in the controller 650. Also, a MIN function may be a function for selecting a smaller value among comparison values.

In the above case, the velocity of the corresponding transporter 630 may increase rapidly without exceeding the maximum velocity set in the controller 650. In this case, the controller 650 may first increase the velocity of the transporter 630 with the lowest velocity among the transporters 630. In another embodiment, the controller 650 may increase the velocity of all transporters 630 by separately applying Equation 4 to each transporter 630. In this case, in the case of adjusting the velocity of a plurality of transporters 630, the velocity of the transporter 630 with the greatest impulse response among the plurality of transporters 630 may be increased the most. That is, because Pₘₖ of the transporter 630 with the great impulse response also increases, the amount of increasing the velocity may be greater than that of other transporters 630.

When determining that the second frequency response is equal to the preset frequency response, the controller 650 may maintain existing state (step S182), e.g. operate the transporter 630 as set in the first schedule.

When the above process is completed, the controller 650 may determine whether the process is completed (S190). When determining that the process is completed, the controller 650 may stop the entirety of the process. When determining that the process is not completed, the controller 650 may repeatedly perform the above process by recalculating the first frequency response, the second frequency response, and the impulse response described above.

Referring to FIG. 3B, the electronic apparatus manufacturing apparatus 600 may be controlled similarly to the description in FIG. 3A. In an embodiment, operations S110 to S160 illustrated in FIG. 3A may be performed, for example. Thereafter, the controller 650 may determine whether the second frequency response is less than a preset frequency response (S170′). When determining that the second frequency response is less than the preset frequency response, the controller 650 may increase the number of transporters 630 arranged in one area or increase the velocity of the transporter 630. In this case, a method of increasing the number of transporters 630 arranged in one area or increasing the velocity of the transporter 630 may be the same as the method described in S181 of FIG. 3A (S171′).

When determining that the second frequency response is not less than the preset frequency response, the controller 650 may determine whether the second frequency response is greater than the preset frequency response (S180′).

When determining that the second frequency response is greater than the preset frequency response, the controller 650 may reduce the number of transporters 630 arranged in one area or reduce the velocity of the transporter 630 (S181′). In this case, a method of reducing the number of transporters 630 arranged in one area or reducing the velocity of the transporter 630 may be the same as the method described in S171′ of FIG. 3A.

When determining that the second frequency response is equal to the preset frequency response, the controller 650 may maintain existing state maintain the process according to the first schedule (S182).

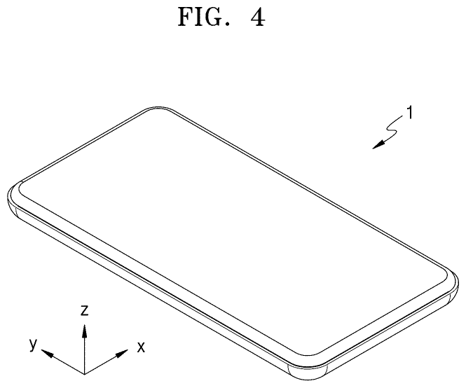

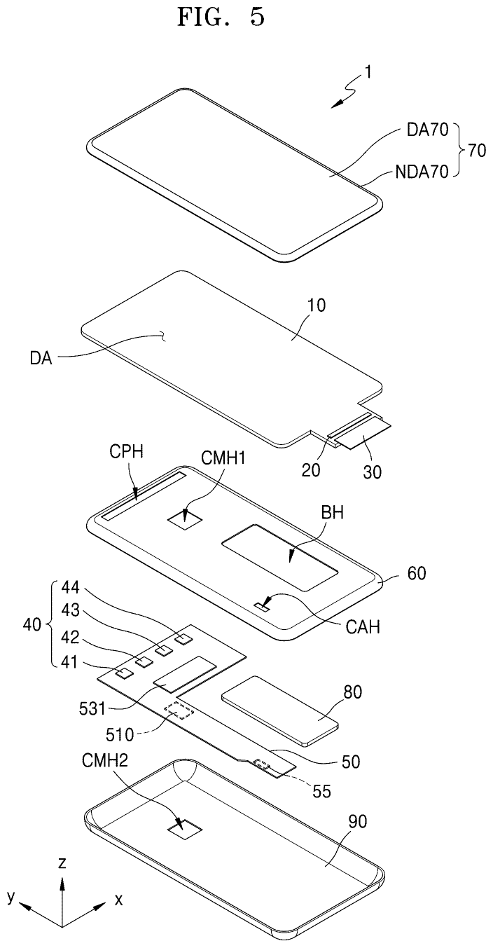

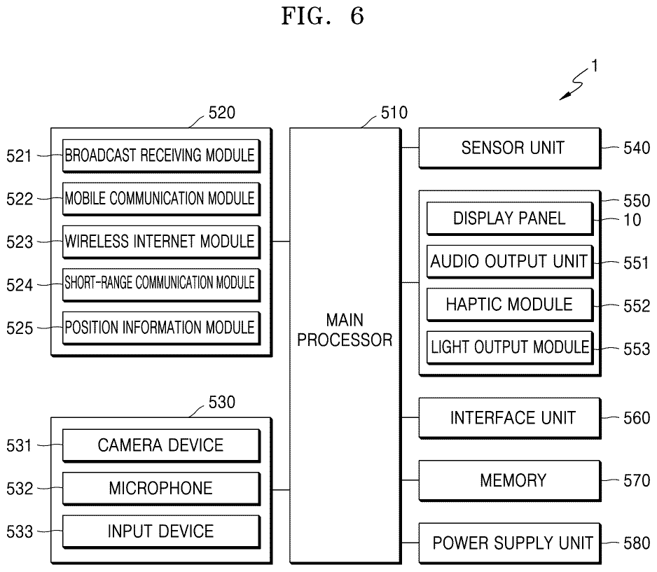

FIG. 4 is a perspective view schematically illustrating an embodiment of a electronic apparatus. FIG. 5 is an exploded perspective view schematically illustrating the electronic apparatus of FIG. 4. FIG. 6 is a block diagram schematically illustrating the electronic apparatus of FIG. 4.

Referring to FIGS. 4 and 5, an electronic apparatus 1 in an embodiment may be an apparatus displaying a moving image or a still image and may be a portable electronic apparatus such as a mobile phone, a smartphone, a tablet personal computer, a mobile communication terminal, an electronic notebook, an electronic book, a portable multimedia player (“PMP”), navigation, or an ultra mobile personal computer (“UMPC”) or may be any of various products such as televisions, notebook computers, monitors, billboards, and Internet of Things (“IoT”). In an alternative embodiment, the electronic apparatus 1 in an embodiment may be a wearable device such as a smart watch, a watch phone, a glasses-type display, or a head-mounted display (“HMD”). In an alternative embodiment, the electronic apparatus 1 in an embodiment may be a vehicle's instrument panel, may be a center information display (“CID”) disposed at a vehicle's center fascia or dashboard, may be a room mirror display replacing a vehicle's side mirror, or may be a display disposed at a rear side of a vehicle's front seat as entertainment for a vehicle's rear seat.

For convenience of description, FIGS. 4 and 5 illustrate that the electronic apparatus 1 in an embodiment is a smartphone. The electronic apparatus 1 may include a cover window 70, a display panel 10, a data driver 20, a display circuit board 30, a component 40, a bracket 60, a main circuit board 50, a battery 80, and/or a lower cover 90.

In the plan view of the specification, “left,” “right,” “up,” and “down” may refer to directions when viewing the display panel 10 in a vertical direction of the display panel 10. In an embodiment, “left” may refer to the −x direction, “right” may refer to the +x direction, “up” may refer to the +y direction, and “down” may refer to the −y direction.

The electronic apparatus 1 may appear to have a substantially quadrangular shape, e.g., rectangular shape in the plan view. In an embodiment, the electronic apparatus 1 may appear to have a substantially quadrangular shape, e.g., rectangular shape having a short side in the x-axis direction and a long side in the y-axis direction on the xy-plane as illustrated in FIG. 4, for example. In this case, the corner where the short side in the x-axis direction and the long side in the y-axis direction meet each other may form a right angle or may have a round shape to have a predetermined curvature. Also, in the plan view, the electronic apparatus 1 may have a polygonal shape other than a quadrangular shape, e.g., rectangular shape or may have an elliptical shape, an atypical shape, or the like.

The cover window 70 may be disposed over the display panel 10 so as to cover the upper surface of the display panel 10. The cover window 70 may protect the upper surface of the display panel 10.

The cover window 70 may include a light-transmitting cover unit DA70 corresponding to the display panel 10 and a light-blocking cover unit NDA70 surrounding the light-transmitting cover unit DA70. The light-blocking cover unit NDA70 may include an opaque material (e.g., a colored opaque material) that blocks light. The light-blocking cover unit NDA70 may include a pattern that may be shown to a user in the case of not displaying an image.

The display panel 10 may be disposed under the cover window 70. The display panel 10 may overlap the light-transmitting cover unit DA70 of the cover window 70. The display panel 10 may include a display area DA. The display area DA may be an area where an image is displayed, and the display area DA may include an area (hereinafter referred to as a component area) that transmits light emitted from the component 40 disposed under the display panel 10. The component 40 may include a sensor or a camera that uses visible light, infrared light, or sound.

The display panel 10 may be a light-emitting display panel including a light-emitting diode. The light-emitting diode may be an organic light-emitting diode including an organic emission layer or may be an inorganic light-emitting diode including an inorganic material. In the case of the inorganic light-emitting diode, it may include a PN junction diode including inorganic semiconductor-based materials. When a forward voltage is applied to the PN junction diode, holes and electrons may be injected thereinto and energy generated by the recombination of the holes and electrons may be converted into light energy to emit light of a predetermined color. The inorganic light-emitting diode may have a width of several micrometers to several hundred micrometers. The inorganic light-emitting diode may be also referred to as a micro light-emitting diode.

The display panel 10 may be a rigid display panel that is rigid and thus is not easily bent or may be a flexible display panel that is flexible and thus may be easily bent, folded, or rolled. In an embodiment, the display panel 10 may be a foldable display panel that may be folded and unfolded, may be a curved display panel with a curved display surface, may be a bent display panel with an area other than a display surface bent, may be a rollable display panel that may be rolled or unrolled, or may be a stretchable display panel that may be stretched, for example.

The display panel 10 may be a transparent display panel that is transparently implemented such that an object or background arranged on the lower surface of the display panel 10 may be viewed from the upper surface of the display panel 10. In an alternative embodiment, the display panel 10 may be a reflective display panel that may reflect an object or background on the upper surface of the display panel 10.

The data driver 20 may be disposed (e.g., mounted) on the display panel 10 in the form of an integrated circuit (“IC”). However, the disclosure is not limited thereto, and for example, the data driver 20 may be disposed (e.g., mounted) on the display circuit board 30.

The display circuit board 30 may be attached to one side of the display panel 10. The display circuit board 30 may be a flexible printed circuit board (“FPCB”) that may be bent, may be a rigid printed circuit board (“PCB”) that is rigid and thus is not easily bent, or may be a composite PCB including both a rigid PCB and an FPCB. A touch sensor driver may be disposed (e.g., mounted) on the display circuit board 30. The touch sensor driver may be formed as an IC. The touch sensor driver may be electrically connected to touch electrodes of a touch screen layer of the display panel 10 through the display circuit board 30.

The touch screen layer of the display panel 10 may detect a user's touch input by at least one of various touch methods such as a resistive method and a capacitive method. When the touch screen layer of the display panel 10 detects a user's touch input by the capacitive method, the touch sensor driver may apply driving signals to driving electrodes among the touch electrodes and detect voltages charged in mutual electrostatic capacitances (hereinafter referred to as “mutual capacitances”) between driving electrodes and sensing electrodes through sensing electrodes among the touch electrodes, thereby determining whether a user's touch has occurred.

The user's touch may include a contact touch and a proximity touch. The contact touch may mean that a user's finger or an object such as a pen directly contacts the cover window 70 disposed over the touch screen layer. The proximity touch may mean that a user's finger or an object such as a pen is disposed close to and apart from the cover window 70, such as hovering. The touch sensor driver may transmit sensor data to a main processor 510 according to the detected voltages, and the main processor 510 may calculate touch coordinates of the touch input by analyzing the sensor data.

A controller for supplying driving voltages for driving pixels, a gate driver, and/or a data driver 20 of the display panel 10 may be disposed over the display circuit board 30.

The bracket 60 for supporting the display panel 10 may be disposed under the display panel 10. The bracket 60 may include plastic, metal, or both plastic and metal. A first camera hole CMH1 into which a camera device 531 is inserted, a battery hole BH in which the battery 80 is disposed, a cable hole CAH through which a cable connected to the display circuit board 30 passes, and a component hole CPH corresponding to components 40 may be defined in the bracket 60. The component hole CPH may overlap the components 40 of the main circuit board 50 when viewed in a third direction (z-axis direction). For reference, the display area DA of the display panel 10 may overlap the components 40 of the main circuit board 50 when viewed in the third direction (z-axis direction). However, when desired, the component hole CPH may not be defined in the bracket 60.

The components 40 included in the electronic apparatus 1 may include a first component 41, a second component 42, a third component 43, and a fourth component 44 that overlap the display panel 10. Each of the first component 41, the second component 42, the third component 43, and the fourth component 44 may include at least one of a proximity sensor, an illuminance sensor, an iris sensor, a face recognition sensor, and a camera (or an image sensor). The proximity sensor using infrared rays may detect an object disposed close to the upper surface of the electronic apparatus 1, and the illuminance sensor may sense the brightness of light incident on the upper surface of the electronic apparatus 1. Also, the iris sensor may photograph a person's iris disposed over the upper surface of the electronic apparatus 1, and the camera may obtain image data about an object disposed over the upper surface of the electronic apparatus 1. However, the components 40 are not limited to a proximity sensor, an illuminance sensor, an iris sensor, a face recognition sensor, and/or a camera and may include other sensors.

The main circuit board 50 and the battery 80 may be arranged under the bracket 60. The main circuit board 50 may be a rigid PCB or an FPCB.

The main circuit board 50 may include a main processor 510, a camera device 531, a main connector 55, and components 40. The main processor 510 may be formed as an IC. When desired, the electronic apparatus 1 may also include a camera device disposed on the lower surface of the main circuit board 50, as well as the camera device 531 disposed on the upper surface of the main circuit board 50. Each of the main processor 510 and the main connector 55 may be arranged on any one of the upper surface and the lower surface of the main circuit board 50. The main circuit board 50 may be electrically connected to the display circuit board 30 through the main connector 55 or the like.

The main processor 510 may control all functions of the electronic apparatus 1. In an embodiment, the main processor 510 may output digital video data to the data driver 20 through the display circuit board 30 such that the display panel 10 may display an image, for example. The main processor 510 may receive sensing data from the touch sensor driver. The main processor 510 may determine whether there is a user touch based on the sensing data and execute an operation corresponding to the user's direct touch or proximity touch. The main processor 510 may be an application processor, a central processing unit, or a system chip including an IC.

The camera device 531 may process an image frame such as a still image or a moving image obtained by an image sensor in a camera mode and output the processed image frame to the main processor 510. The camera device 531 may include at least one of a camera sensor (e.g., charge-coupled device (“CCD”) or complementary metal-oxide-semiconductor (“CMOS”)), a photo sensor (or an image sensor), and a laser sensor.

A cable passing through the cable hole CAH of the bracket 60 may be connected to the main connector 55, and the main circuit board 50 may be electrically connected to the display circuit board 30 through the cable.

The electronic apparatus 1 may be represented by the block diagram illustrated in FIG. 6. In addition to the main processor 510, the electronic apparatus 1 may include a wireless communicator 520, an input unit 530, a sensor unit 540, an output unit 550, an interface unit 560, a memory 570, and/or a power supply unit 580 as illustrated in FIG. 6.

The wireless communicator 520 may include at least one of a broadcast receiving module 521, a mobile communication module 522, a wireless Internet module 523, a short-range communication module 524, and a position information module 525.

The broadcast receiving module 521 may receive broadcast signals and/or broadcast-related information from an external broadcast management server through broadcast channels. The broadcast channels may include satellite channels and terrestrial channels.

The mobile communication module 522 may transmit/receive wireless signals to/from at least one of a base station, an external terminal, and a server in a mobile communication network established according to technology standards or communication methods for mobile communication (e.g., Global System for Mobile communication (“GSM”), Code Division Multi Access (“CDMA”), Code Division Multi Access 2000 (“CDMA2000”), Enhanced Voice-Data Optimized or Enhanced Voice-Data Only (“EV-DO”), Wideband CDMA (“WCDMA”), High Speed Downlink Packet Access (“HSDPA”), High Speed Uplink Packet Access (“HSUPA”), Long Term Evolution (“LTE”), and Long Term Evolution-Advanced (“LTE-A”)). The wireless signals may include various forms of data according to voice call signals, video call signals, or text/multimedia message transmission/reception.

The wireless Internet module 523 may refer to a module for wireless Internet access. The wireless Internet module 523 may transmit/receive wireless signals in a communication network according to wireless Internet technologies. The wireless Internet technologies may be Wireless LAN (“WLAN”), Wireless Fidelity (“WiFi”), WiFi Direct, and/or Digital Living Network Alliance (“DLNA”), for example.

The short-range communication module 524 may be for short-range communication and may support short-range communication by at least one of Bluetooth™, Radio Frequency Identification (“RFID”), Infrared Data Association (“IrDA”), Ultra Wideband (“UWB”), ZigBee, Near Field Communication (“NFC”), WiFi, WiFi Direct, and Wireless Universal Serial Bus (“Wireless USB”) technologies. The short-range communication module 524 may support wireless communication between the electronic apparatus 1 and a wireless communication system, between the electronic apparatus 1 and another electronic apparatus, or between the electronic apparatus 1 and a network in which another electronic apparatus (or an external server) is disposed, through a short-range wireless communication network (Wireless Area Network). The short-range wireless communication network may be a short-range wireless personal area network (Wireless Personal Area Network). a remaining (the other) electronic apparatus may be a wearable device capable of exchanging data (or capable of interoperating) with the electronic apparatus 1.

The position information module 525 may be a module for obtaining the position of the electronic apparatus 1 and may include a Global Positioning System (“GPS”) module or a WiFi module.

The input unit 530 may include an image input unit such as a camera device 531 for inputting an image signal, an audio input unit such as a microphone 532 for inputting an audio signal, and an input device 533 for receiving information from the user. The camera device 531 may process an image frame such as a still image or a moving image obtained by an image sensor in a video call mode or a photographing mode. The processed image frame may be displayed on the display panel 10 or stored in the memory 570. The microphone 532 may process an external audio signal into electrical voice data. The processed voice data may be variously used depending on the functions performed (or the applications executed) in the electronic apparatus 1.

The main processor 510 may control the operation of the electronic apparatus 1 to correspond to information input through the input device 533. The input device 533 may include a mechanical input unit or a touch input unit such as a button, a dome switch, a jog wheel, or a jog switch disposed on the rear surface or side surface of the electronic apparatus 1. The touch input unit may include a touch screen layer of the display panel 10.

The sensor unit 540 may include one or more sensors that sense at least one of information in the electronic apparatus 1, information about the surrounding environment surrounding the electronic apparatus 1, and user information and generate a sensing signal corresponding thereto. The main processor 510 may control the driving or operation of the electronic apparatus 1 based on the sensing signal or perform data processing, functions, or operations related to the application installed on the electronic apparatus 1. The sensor unit 540 may be a proximity sensor, an illuminance sensor, or a face recognition sensor as described above with respect to the component 40. Also, the sensor unit 540 may include an acceleration sensor, a magnetic sensor, a gravity sensor (G-sensor), a gyroscope sensor, a motion sensor, an RGB sensor, an infrared sensor (IR sensor), a fingerprint recognition sensor (finger scan sensor), an ultrasonic sensor, an optical sensor, and/or a battery gauge. In addition, the sensor unit 540 may include an environmental sensor or a chemical sensor. The environmental sensor may be a barometer, a hygrometer, a thermometer, a radiation detection sensor, a heat detection sensor, and/or a gas detection sensor, for example. The chemical sensor may be an electronic nose, a healthcare sensor, and/or a biometric sensor, for example.

The output unit 550 may be for generating an output related to visual, auditory or tactile sensation and may include at least one of a display panel 10, an audio output unit 551, a haptic module 552, and a light output unit 553.

The display panel 10 may display (output) information processed in the electronic apparatus 1. In an embodiment, the display panel 10 may display execution screen information of an application driven in the electronic apparatus 1, display a user interface (“UI”) according to the execution screen information, or display graphical UI (“GUI”) information, for example. The display panel 10 may include a display layer for displaying an image and a touch screen layer for detecting a user's touch input. Accordingly, the display panel 10 may function as one of input devices 533 providing an input interface between the electronic apparatus 1 and the user and may simultaneously function as one of output units 550 providing an output interface between the electronic apparatus 1 and the user.

The audio output unit 551 may output audio data received from the wireless communicator 520 or stored in the memory 570, in a call signal reception mode, a call mode, a recording mode, a voice recognition mode, and/or a broadcast reception mode. The audio output unit 551 may also output an audio signal related to a function performed in the electronic apparatus 1 (e.g., a call signal reception sound or a message reception sound). The audio output unit 551 may include a receiver and a speaker. At least one of the receiver and the speaker may be an audio generating device that is attached to the lower portion of the display panel 10 and vibrates the display panel 10 to output audio. The audio generating device may be a piezoelectric element or a piezoelectric actuator that contracts and expands according to an electric signal or may be an exciter that vibrates the display panel 10 by generating a magnetic force by a voice coil.

The haptic module 552 may generate various tactile effects that the user may feel. The haptic module 552 may provide a vibration as a tactile effect to the user. The haptic module 552 not only may transmit a tactile effect through direct contact but also may be implemented such that the user may feel a tactile effect through a muscle sense of the fingers, arms, or the like.

The light output unit 553 may output a signal for notifying the occurrence of an event by light of a light source. In an embodiment, the event occurring in the electronic apparatus 1 may include message reception, call signal reception, missed call, alarm, schedule notification, email reception, and/or information reception through an application. The signal output from the light output unit 553 may be implemented by the electronic apparatus 1 emitting light of a single color or a plurality of colors from the front surface or rear surface. The signal output may be terminated when the electronic apparatus 1 detects the user's identification of an event.

The interface unit 560 may function as a path for various types of external devices connected to the electronic apparatus 1. The interface unit 560 may include at least one of a wired/wireless headset port, an external charger port, a wired/wireless data port, a memory card port, a port for connecting a device including an identification module, an audio input/output (“I/O”) port, a video I/O port, and an earphone port. When an external device is connected to the interface unit 560, the electronic apparatus 1 may perform suitable control related to the connected external device.

The memory 570 may store data for supporting various functions of the electronic apparatus 1. The memory 570 may store a plurality of applications (application programs) driven in the electronic apparatus 1, data for the operation of the electronic apparatus 1, and/or instructions. At least some of the plurality of applications may be downloaded from an external server through wireless communication. The memory 570 may store an application for the operation of the main processor 510 and may temporarily store I/O data such as a phonebook, a message, a still image, and/or a moving image. Also, the memory 570 may store haptic data for various patterns of vibrations provided to the haptic module 552 and audio data about various audios provided to the audio output unit 551.

The memory 570 may include at least one type of storage medium from among flash memory type, hard disk type, solid state disk (“SSD”) type, silicon disk drive (“SDD”) type, multimedia card micro type, card type memory (e.g., secure digital (“SD”) and extreme digital (“XD”) memories), random-access memory (“RAM”), static random-access memory (“SRAM”), read-only memory (“ROM”), electronically erasable programmable read-only memory (“EEPROM”), programmable read-only memory (“PROM”), magnetic memory, magnetic disk, and optical disk.

Under the control by the main processor 510, the power supply unit 580 may receive external power and/or internal power and supply the power to each of the components included in the electronic apparatus 1. The power supply unit 580 may include a battery 80. Also, the power supply unit 580 may include a connection port, and the connection port may be an embodiment of the interface unit 560 to which an external charger supplying power for charging the battery is electrically connected. In an alternative embodiment, the power supply unit 580 may allow the battery 80 to be wirelessly charged. The battery 80 may be disposed so as not to overlap the main circuit board 50 in the third direction (z-axis direction). The battery 80 may overlap the battery hole BH of the bracket 60.

The lower cover 90 may form the external shape of the electronic apparatus 1 and may define an opening that exposes a portion of the display panel 10. The lower cover 90 may have an open shape corresponding to the display panel 10 and may be fastened to the display panel 10. The lower cover 90 may be disposed on the opposite side of the cover window 70 with the display panel 10 therebetween. The lower cover 90 may be disposed under the main circuit board 50 and the battery 80. The lower cover 90 may be fastened and fixed to the bracket 60. The lower cover 90 may form the external shape of the lower surface of the electronic apparatus 1. The lower cover 90 may include plastic, metal, or both plastic and metal.

A second camera hole CMH2 may be defined in the lower cover 90 to expose the lower surface of the camera device 531. The position of the camera device 531 and the positions of the first camera hole CMH1 and the second camera hole CMH2 corresponding to the camera device 531 are not limited to those illustrated in FIG. 5 and may be variously modified.

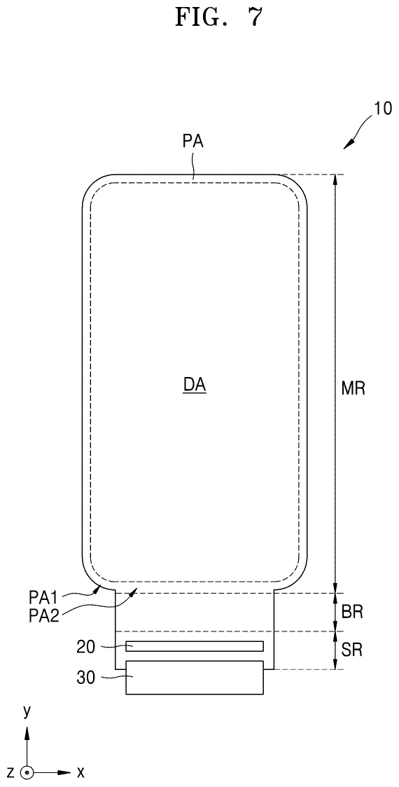

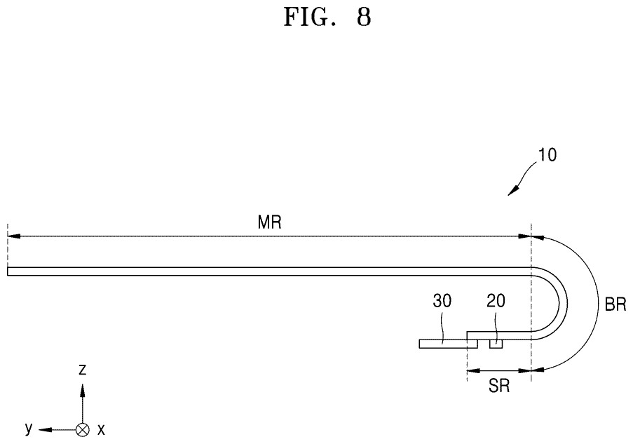

FIG. 7 is a plan view schematically illustrating an embodiment of a portion of the electronic apparatus. FIG. 8 is a side view schematically illustrating a portion of the electronic apparatus illustrated in FIG. 7.

Referring to FIGS. 7 and 8, a display panel 10 may include a display area DA and a peripheral area PA outside the display area DA. The display area DA may be an area for displaying an image, and a plurality of pixels may be arranged in the display area DA. In an embodiment, the display area DA may have any of various shapes such as a circular shape, an elliptical shape, a polygonal shape, and a particular figure shape, for example. FIG. 7 illustrates that the display area DA has a substantially quadrangular shape, e.g., rectangular shape with rounded corners.

The peripheral area PA may be disposed outside the display area DA. The peripheral area PA may include a first peripheral area PA1 disposed to surround at least a portion of the display area DA and a second peripheral area PA2 disposed under the display area DA and extending in the first direction (x-axis direction). The width of the second peripheral area PA2 in the first direction (x-axis direction) may be less than the width of the display area DA. Through this structure, at least a portion of the second peripheral area PA2 may be easily bent.

The planar shape of the display panel 10 illustrated in FIG. 7 may be substantially the same as the shape of a substrate 100 included in the display panel 10. When the display panel 10 includes the display area DA and the peripheral area PA outside the display area DA, it may be considered that the substrate 100 includes the display area DA and the peripheral area PA outside the display area DA. Hereinafter, for convenience, it will be described that the substrate 100 includes the display area DA and the peripheral area PA.

The display panel 10 may include a main region MR, a bending region BR outside the main region MR, and a sub-region SR spaced apart from the main region MR with the bending region BR therebetween. The main region MR may be disposed on one side of the bending region BR, and the sub-region SR may be disposed on an opposite side of the bending region BR. The display panel 10 may be bent in the bending region BR as illustrated in FIG. 8, and at least a portion of the sub-region SR may overlap the main region MR when viewed in the third direction (z-axis direction). Although FIG. 8 illustrates that the display panel 10 is bent, the disclosure is not limited thereto. In an embodiment, the display panel 10 may be a foldable display panel, and in this case, the display panel 10 may be bent in the display area DA around a bending axis intersecting the display area DA, for example. However, when desired, the display panel 10 may not be bent. The sub-region SR may be a non-display area.

A data driver 20 may be disposed in the sub-region SR of the display panel 10. The data driver 20 may be disposed on the display panel 10 in the form of an IC. In an embodiment, the data driver 20 may be a data driving IC that generates a data signal, for example.

A display circuit board 30 may be attached to an end portion of the sub-region SR of the display panel 10. The display circuit board 30 may be electrically connected to the data driver 20 or the like through a pad of the sub-region SR of the display panel 10.

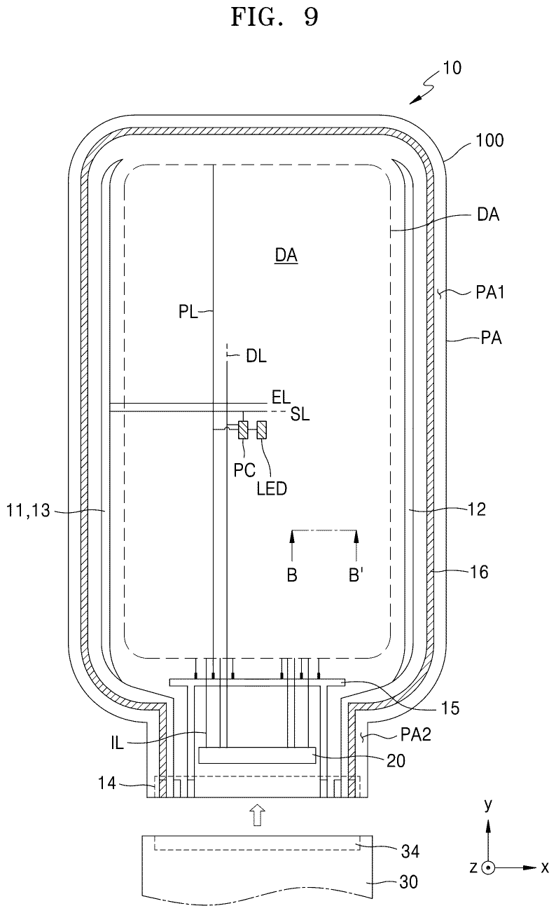

FIG. 9 is a plan view schematically illustrating a portion of the electronic apparatus illustrated in FIG. 7.

Referring to FIG. 9, the display panel 10 may include a substrate 100. Various components included in the display panel 10 may be arranged over the substrate 100.

The substrate 100 may include glass, ceramic, metal, or polymer resin. The substrate 100 may include a polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multilayer structure including two layers including the polymer resin and an inorganic layer disposed between the two layers. In an alternative embodiment, the substrate 100 may have a structure in which layers including the polymer resin and inorganic layers are alternately stacked. The inorganic layer may include silicon oxide, silicon nitride, or silicon oxynitride, for example.

Pixels may be arranged in the display area DA, and the display area DA may provide an image by light emitted from the pixels. Each pixel may include a light-emitting element (e.g., light-emitting diode) LED, and the light-emitting element LED may be electrically connected to a pixel circuit PC. The pixel circuit PC and the light-emitting element LED may be arranged in the display area DA. For convenience, FIG. 9 illustrates that the pixel circuit PC and the light-emitting element LED are disposed in parallel; however, in actuality, the pixel circuit PC and the light-emitting element LED may at least partially overlap each other. In an embodiment, the light-emitting element LED may be disposed over the pixel circuit PC, for example.

A gate driving circuit, a pad 14, a first power supply line 15, and a second power supply line 16 may be disposed in the peripheral area PA. The gate driving circuit may include a first scan driving circuit 11, a second scan driving circuit 12, and/or an emission control driving circuit 13, for example.

The first scan driving circuit 11 may provide a scan signal to the pixel circuit PC through a scan line SL. The second scan driving circuit 12 may be disposed on the opposite side of the first scan driving circuit 11 with the display area DA therebetween. Some of the pixel circuits PC disposed in the display area DA may be electrically connected to the first scan driving circuit 11, and remaining (the other) pixel circuits PC may be connected to the second scan driving circuit 12. However, in some cases, the second scan driving circuit 12 may be omitted.

Like the first scan driving circuit 11, the emission control driving circuit 13 may be disposed on one side of the display area DA. The emission control driving circuit 13 may provide an emission control signal to a pixel circuit PC through an emission control line EL. FIG. 9 illustrates that the emission control driving circuit 13 is disposed only on one side of the display area DA; however, the disclosure is not limited thereto. In an embodiment, the display panel 10 may include emission control driving circuits 13 arranged on one side and an opposite side of the display area DA, for example. In an alternative embodiment, the first scan driving circuit 11 may be disposed on one side of the display area DA, and the emission control driving circuit 13 may be disposed on an opposite side thereof.

The pad 14 may be disposed in the second peripheral area PA2 of the substrate 100. The pad 14 may be exposed by not being covered by an insulating layer and may be electrically connected to the display circuit board 30. A pad 34 of the display circuit board 30 may be electrically connected to the pad 14 of the display panel 10.

The display circuit board 30 may transmit a signal of a controller or power to the display panel 10. A control signal generated by the controller may be transmitted to each gate driving circuit through the display circuit board 30. Also, the controller may provide a first power voltage (also referred to as driving voltage) ELVDD and a second power voltage (also referred to as common voltage) ELVSS to the first power supply line 15 and the second power supply line 16. The first power voltage ELVDD may be provided to each pixel circuit PC through a driving voltage line PL connected to the first power supply line 15, and the second power voltage ELVSS may be provided to a common electrode of the light-emitting element LED connected to the second power supply line 16. The first power supply line 15 may extend in the first direction (x-axis direction). The second power supply line 16 may have a loop shape with one side open and thus may partially surround the display area DA.

A data signal of the data driver 20 may be transmitted through an input line IL to the pixel circuit PC through a data line DL electrically connected to the input line IL.

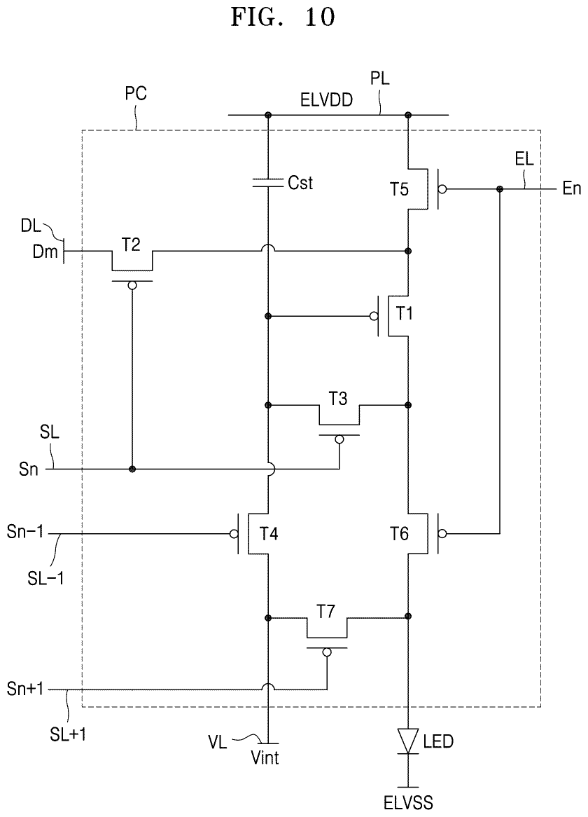

FIG. 10 is an equivalent circuit diagram of a pixel disposed in a display area of a display panel illustrated in FIG. 9.

Referring to FIG. 10, the light-emitting element LED may be electrically connected to the pixel circuit PC.

The pixel circuit PC may include a first thin film transistor T1, a second thin film transistor T2, a third thin film transistor T3, a fourth thin film transistor T4, a fifth thin film transistor T5, a sixth thin film transistor T6, a seventh thin film transistor T7, and a storage capacitor Cst.

As a switching thin film transistor, the second thin film transistor T2 may be connected to a scan line SL and a data line DL and may transmit a data voltage (or a data signal) Dm input from the data line DL to the first thin film transistor T1, based on a switching voltage (or a switching signal) Sn input from the scan line SL. The storage capacitor Cst may be connected to the second thin film transistor T2 and a driving voltage line PL and may store a voltage corresponding to the difference between a voltage received from the second thin film transistor T2 and a first power voltage ELVDD supplied to the driving voltage line PL.

As a driving thin film transistor, the first thin film transistor T1 may be connected to the driving voltage line PL and the storage capacitor Cst and may control a driving current flowing from the driving voltage line PL through the light-emitting element LED in response to a value of voltage stored in the storage capacitor Cst. The light-emitting element LED may emit light with a predetermined brightness according to the driving current. A second electrode (e.g., a cathode) of the light-emitting element LED may be supplied with a second power voltage ELVSS.

The third thin film transistor T3 may be a compensation thin film transistor, and the gate electrode of the third thin film transistor T3 may be connected to the scan line SL. The source electrode (or drain electrode) of the third thin film transistor T3 may be connected to the drain electrode (or source electrode) of the first thin film transistor T1 and may be connected to a first electrode of the light-emitting element LED via the sixth thin film transistor T6. The drain electrode (or source electrode) of the third thin film transistor T3 may be connected to any one electrode of the storage capacitor Cst, the source electrode (or drain electrode) of the fourth thin film transistor T4, and the gate electrode of the first thin film transistor T1. The third thin film transistor T3 may be turned on according to a scan signal Sn received through the scan line SL, to connect the gate electrode and the drain electrode of the first thin film transistor T1 to each other to diode-connect the first thin film transistor T1.

The fourth thin film transistor T4 may be an initialization thin film transistor and the gate electrode thereof may be connected to a previous scan line SL−1. The drain electrode (or source electrode) of the fourth thin film transistor T4 may be connected to an initialization voltage line VL. The source electrode (or drain electrode) of the fourth thin film transistor T4 may be connected to the one electrode of the storage capacitor Cst, the drain electrode (or source electrode) of the third thin film transistor T3, and the gate electrode of the first thin film transistor T1. The fourth thin film transistor T4 may be turned on according to a previous scan signal Sn−1 received through the previous scan line SL−1, to transmit an initialization voltage Vint to the gate electrode of the first thin film transistor T1 to perform an initialization operation of initializing the voltage of the gate electrode of the first thin film transistor T1.

The fifth thin film transistor T5 may be an operation control thin film transistor and the gate electrode thereof may be connected to an emission control line EL. The source electrode (or drain electrode) of the fifth thin film transistor T5 may be connected to the driving voltage line PL. The drain electrode (or source electrode) of the fifth thin film transistor T5 may be connected to the source electrode (or drain electrode) of the first thin film transistor T1 and the drain electrode (or source electrode) of the second thin film transistor T2.

The sixth thin film transistor T6 may be an emission control thin film transistor and the gate electrode thereof may be connected to the emission control line EL. The source electrode (or drain electrode) of the sixth thin film transistor T6 may be connected to the drain electrode (or source electrode) of the first thin film transistor T1 and the source electrode (or drain electrode) of the third thin film transistor T3. The drain electrode (or source electrode) of the sixth thin film transistor T6 may be electrically connected to the first electrode of the light-emitting element LED. The fifth thin film transistor T5 and the sixth thin film transistor T6 may be simultaneously turned on according to an emission control signal En received through the emission control line EL, such that the first power voltage ELVDD may be transmitted to the light-emitting element LED and the driving current may flow through the light-emitting element LED.

The seventh thin film transistor T7 may be an initialization thin film transistor that initializes the first electrode of the light-emitting element LED. The gate electrode of the seventh thin film transistor T7 may be connected to a next scan line SL+1. The source electrode (or drain electrode) of the seventh thin film transistor T7 may be connected to the first electrode of the light-emitting element LED. The drain electrode (or source electrode) of the seventh thin film transistor T7 may be connected to the initialization voltage line VL. The seventh thin film transistor T7 may be turned on according to a next scan signal Sn+1 received through the next scan line SL+1, to initialize the first electrode of the light-emitting element LED.

FIG. 10 illustrates a case where the fourth thin film transistor T4 and the seventh thin film transistor T7 are respectively connected to the previous scan line SL−1 and the next scan line SL+1; however, in another embodiment, both the fourth thin film transistor T4 and the seventh thin film transistor T7 may be connected to the previous scan line SL−1 to be driven according to the previous scan signal Sn−1.

Another electrode of the storage capacitor Cst may be connected to the driving voltage line PL. The one electrode of the storage capacitor Cst may be connected to the gate electrode of the first thin film transistor T1, the drain electrode (or source electrode) of the third thin film transistor T3, and the source electrode (or drain electrode) of the fourth thin film transistor T4.

The second electrode (e.g., cathode) of the light-emitting element LED may be provided with the second power voltage ELVSS. The light-emitting element LED may emit light by receiving a driving current from the first thin film transistor T1.

The light-emitting element LED may be an organic light-emitting diode including an organic material as a light-emitting material. In another embodiment, the light-emitting element LED may be an inorganic light-emitting diode including an inorganic material. The inorganic light-emitting diode may include a PN junction diode including inorganic semiconductor-based materials. When a forward voltage is applied to the PN junction diode, holes and electrons may be injected thereinto and energy generated by the recombination of the holes and electrons may be converted into light energy to emit light of a predetermined color. The inorganic light-emitting diode described above may have a width of several to several hundred micrometers or several to several hundred nanometers. In some embodiments, the light-emitting element LED may include a quantum dot light-emitting diode. As described above, an emission layer of the light-emitting element LED may include an organic material, may include an inorganic material, may include quantum dots, may include an organic material and quantum dots, or may include an inorganic material and quantum dots. Hereinafter, for convenience of description, a case where the light-emitting element LED includes an organic light-emitting diode will be described as an example.

FIG. 10 illustrates that the pixel circuit PC includes seven transistors and one capacitor; however, in another embodiment, the pixel circuit PC may include two or more transistors and two or more capacitors. Also, the circuit design of the pixel circuit PC is not limited to the illustration in FIG. 10 and may be variously modified.

At least one of the first to seventh thin film transistors T1, T2, T3, T4, T5, T6, and T7 may be P-channel metal oxide semiconductor field effect transistor (“P-channel MOSFET” or “PMOS”), and remaining (the other) transistors may be N-channel MOSFET (or “NMOS”). In an alternative embodiment, all of the first to seventh thin film transistors T1, T2, T3, T4, T5, T6, and T7 may be NMOS or may be PMOS. The positions of sources and drains may be interchanged with each other depending on the types (P-type or N-type) of transistors.

All of the first to seventh thin film transistors T1, T2, T3, T4, T5, T6, and T7 illustrated in FIG. 10 may be transistors including a low-temperature polysilicon semiconductor layer. In this case, the first to seventh thin film transistors T1, T2, T3, T4, T5, T6, and 17 illustrated in FIG. 10 are not limited thereto, and at least one of the first to seventh thin film transistors T1, T2, T3, T4, T5, T6, and T7 may be a transistor including a low-temperature polycrystalline silicon (“LTPS”) semiconductor layer and remaining (the other) transistors may be transistors including an oxide semiconductor layer. In an alternative embodiment, all of the first to seventh thin film transistors T1, T2, T3, T4, T5, T6, and T7 may be transistors including an oxide semiconductor layer or may be transistors including a low-temperature polysilicon semiconductor layer.

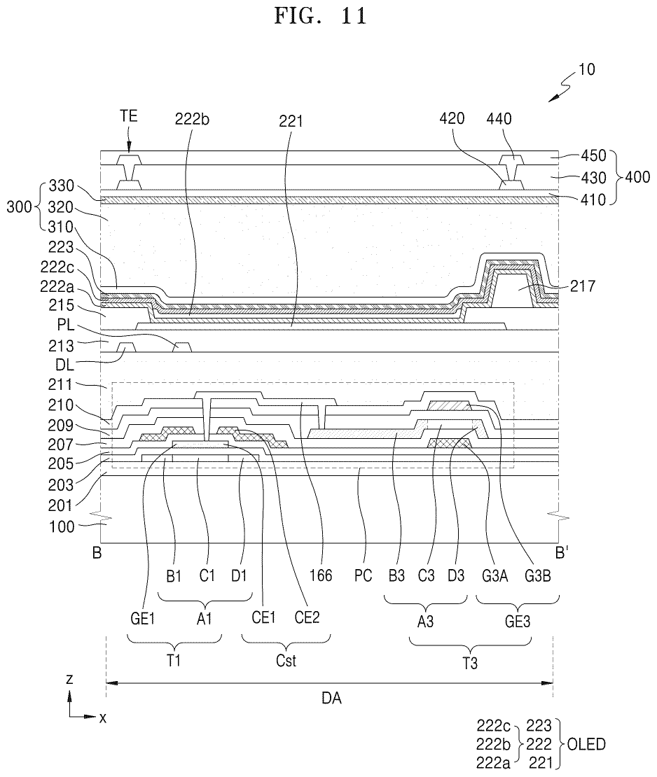

FIG. 11 is a cross-sectional view schematically illustrating a portion of the display panel illustrated in FIG. 9. FIG. 11 is a cross-sectional view of the display panel taken along line B-B′ of FIG. 9.

Referring to FIG. 11, a pixel circuit PC and a light-emitting diode, e.g., an organic light-emitting diode OLED, arranged in the display area DA of the display panel are illustrated.

The substrate 100 may include glass, ceramic, metal, or polymer resin. In an embodiment, the substrate 100 may have an alternating stack structure of a base layer including a polymer resin and a barrier layer including an inorganic insulating material such as silicon oxide or silicon nitride. When the substrate 100 includes a stack structure of a base layer including a polymer resin and a barrier layer including an inorganic insulating material, the flexibility of the electronic apparatus 1 may be improved and thus a foldable electronic apparatus 1 may be provided.

The inorganic insulating material may include silicon oxide, silicon nitride, or silicon oxynitride.

The polymer resin may include polyethersulphone, polyacrylate, polyetherimide, polyethylene naphthalate, polyethylene terephthalate, polyphenylene sulfide, polyarylate, polyimide, polycarbonate, or cellulose acetate propionate. Hereinafter, for convenience of description, a case where the substrate 100 includes glass will be mainly described in detail.

A pixel circuit PC may be formed over the substrate 100, and a light-emitting diode, e.g., an organic light-emitting diode OLED, may be formed over the pixel circuit PC.

Before the pixel circuit PC is formed over the substrate 100, a buffer layer 201 for preventing impurities from penetrating into the pixel circuit PC may be formed over the substrate 100. The buffer layer 201 may include an inorganic insulating material such as silicon nitride, silicon oxynitride, or silicon oxide and may include a single-layer or multiple-layer structure including the inorganic insulating material.

The pixel circuit PC may include a plurality of transistors and a storage capacitor as described above with reference to FIG. 10. In this regard, FIG. 11 illustrates a first thin film transistor T1, a third thin film transistor T3, and a storage capacitor Cst.

The first thin film transistor T1 may include a semiconductor layer (hereinafter also referred to as first semiconductor layer) A1 over the buffer layer 201 and a gate electrode (hereinafter also referred to as first gate electrode) GE1 overlapping a channel area C1 of the first semiconductor layer A1. The first semiconductor layer A1 may include a silicon-based semiconductor material, e.g., polysilicon. The first semiconductor layer A1 may include a channel area C1 and a first area B1 and a second area D1 arranged on opposite sides of the channel area C1. The first area B1 and the second area D1 may be areas including a higher concentration of impurities than the channel area C1, and one of the first area B1 and the second area D1 may correspond to a source area and a remaining (the other) one may correspond to a drain area.

A first gate insulating layer 203 may be disposed between the first semiconductor layer A1 and the first gate electrode GE1. The first gate insulating layer 203 may include an inorganic insulating material such as silicon oxide, silicon nitride, or silicon oxynitride and may include a single-layer or multilayer structure including the inorganic insulating material.

The first gate electrode GE1 may include a conductive material including molybdenum (Mo), aluminum (Al), copper (Cu), titanium (Ti), or the like and may include a single-layer or multiple-layer structure including the conductive material.

The storage capacitor Cst may include a lower electrode CE1 and an upper electrode CE2 overlapping each other. In an embodiment, the lower electrode CE1 of the storage capacitor Cst may include the first gate electrode GE1. In other words, the first gate electrode G1 may include the lower electrode CE1 of the storage capacitor Cst. In an embodiment, the first gate electrode GE1 and the lower electrode CE1 of the storage capacitor Cst may be unitary with each other, for example.

A first inter-insulating layer 205 may be disposed between the lower electrode CE1 and the upper electrode CE2 of the storage capacitor Cst. The first inter-insulating layer 205 may include an inorganic insulating material such as silicon oxide, silicon nitride, or silicon oxynitride and may include a single-layer or multilayer structure including the inorganic insulating material.

The upper electrode CE2 of the storage capacitor Cst may include a low-resistance conductive material such as molybdenum (Mo), aluminum (Al), copper (Cu), and/or titanium (Ti) and may include a single-layer or multiple-layer structure including the low-resistance conductive material.

A second inter-insulating layer 207 may be disposed over the storage capacitor Cst. The second inter-insulating layer 207 may include an inorganic insulating material such as silicon oxide, silicon nitride, or silicon oxynitride and may include a single-layer or multilayer structure including the inorganic insulating material.

A semiconductor layer (hereinafter also referred to as third semiconductor layer) A3 of the third thin film transistor T3 may be disposed over the second inter-insulating layer 207. The third semiconductor layer A3 may include a silicon-based semiconductor material, e.g., polysilicon.

The third semiconductor layer A3 may include a channel area C3 and a first area B3 and a second area D3 arranged on opposite sides of the channel area C3. One of the first area B3 and the second area D3 may be a source area, and a remaining (the other) one may be a drain area.

The third thin film transistor T3 may include a gate electrode (hereinafter also referred to as third gate electrode) GE3 overlapping the channel area C3 of the third semiconductor layer A3. The third gate electrode GE3 may have a dual-gate structure including a lower gate electrode G3A disposed under the third semiconductor layer A3 and an upper gate electrode G3B disposed over the channel area C3.

The lower gate electrode G3A may be disposed in the same layer (e.g., the first inter-insulating layer 205) as the upper electrode CE2 of the storage capacitor Cst. The lower gate electrode G3A may include the same material as that of the upper electrode CE2 of the storage capacitor Cst.

The upper gate electrode G3B may be disposed over the third semiconductor layer A3 with a second gate insulating layer 209 therebetween. The second gate insulating layer 209 may include an inorganic insulating material such as silicon oxide, silicon nitride, or silicon oxynitride and may include a single-layer or multilayer structure including the inorganic insulating material.

A third inter-insulating layer 210 may be disposed over the upper gate electrode G3B. The third inter-insulating layer 210 may include an inorganic insulating material such as silicon oxynitride and may include a single-layer or multilayer structure including the inorganic insulating material.

As described above with reference to FIG. 10, FIG. 11 illustrates the first thin film transistor T1 and the third thin film transistor T3 among the plurality of thin film transistors and illustrates that the first semiconductor layer A1 and the third semiconductor layer A3 are arranged in different layers; however, the disclosure is not limited thereto.

The second, fourth, fifth, sixth, and seventh thin film transistors T2, T4, T5, T6, and T7 (refer to FIG. 10) described above with reference to FIG. 10 may have the same structure as that of the first thin film transistor T1 described with reference to FIG. 11. In an embodiment, the second, fourth, fifth, sixth, and seventh thin film transistors T2, T4, T5, T6, and T7 (refer to FIG. 4) may include a semiconductor layer disposed in the same layer as the first semiconductor layer A1 of the first thin film transistor T1 and a gate electrode disposed in the same layer as the first gate electrode GE1 of the first thin film transistor T1, for example. The semiconductor layers of the second, fourth, fifth, sixth, and seventh thin film transistors T2, T4, T5, T6, and T7 (refer to FIG. 10) may be integrally connected to the first semiconductor layer A1.

The first thin film transistor T1 and the third thin film transistor T3 may be electrically connected through a node connection line 166. The node connection line 166 may be disposed over the third inter-insulating layer 210. One side of the node connection line 166 may be connected to the first gate electrode GE1 of the first thin film transistor T1, and an opposite side of the node connection line 166 may be connected to the third semiconductor layer A3 of the third thin film transistor T3.

The node connection line 166 may include aluminum (Al), copper (Cu), and/or titanium (Ti) and may include a single layer or multiple layers including the above material. In an embodiment, the node connection line 166 may have a three-layer structure of titanium layer/aluminum layer/titanium layer, for example.

A first organic insulating layer 211 may be disposed over the node connection line 166. The first organic insulating layer 211 may include an organic insulating material. The organic insulating material may include acryl, benzocyclobutene (“BCB”), polyimide, hexamethyldisiloxane (“HMDSO”), or the like.

A data line DL and a driving voltage line PL may be arranged over the first organic insulating layer 211 and may be covered by a second organic insulating layer 213. The data line DL and the driving voltage line PL may include aluminum (Al), copper (Cu), and/or titanium (Ti) and may include a single layer or multiple layers including the above material. In an embodiment, the data line DL and the driving voltage line PL may have a three-layer structure of titanium layer/aluminum layer/titanium layer, for example.

The second organic insulating layer 213 may include an organic insulating material such as acryl, BCB, polyimide, and/or HMDSO. FIG. 11 illustrates that the data line DL and the driving voltage line PL are formed on the first organic insulating layer 211; however, the disclosure is not limited thereto. In another embodiment, any one of the data line DL and the driving voltage line PL may be disposed in the same layer as the node connection line 166, e.g., on the third inter-insulating layer 210.

The light-emitting diode, e.g., the organic light-emitting diode OLED may be disposed over the second organic insulating layer 213.

A first electrode 221 of the organic light-emitting diode OLED may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any combinations thereof. In another embodiment, the first electrode 221 may further include a conductive oxide layer over and/or under the above reflective layer. The conductive oxide layer may include indium tin oxide (“ITO”), indium zinc oxide (“IZO”), zinc oxide (ZnO), indium oxide (In₂O₃), indium gallium oxide (“IGO”), and/or aluminum zinc oxide (“AZO”). In an embodiment, the first electrode 221 may include a three-layer structure of ITO layer/Ag layer/ITO layer.

A bank layer 215 may be disposed over the first electrode 221. The bank layer 215 may define an opening overlapping the first electrode 221 and may cover the edge of the first electrode 221. The bank layer 215 may include an organic insulating material such as polyimide.

An intermediate layer 222 may include an emission layer 222b. The intermediate layer 222 may include a first functional layer 222a disposed under the emission layer 222b and/or a second functional layer 222c disposed over the emission layer 222b. The emission layer 222b may include a high-molecular or low-molecular weight organic material for emitting light of a predetermined color. The first functional layer 222a may include a hole transport layer (“HTL”) and/or a hole injection layer (“HIL”). The second functional layer 222c may include an electron transport layer (“ETL”) and/or an electron injection layer (“EIL”). The first functional layer 222a and the second functional layer 222c may include an organic material.

A second electrode 223 may include a conductive material having a relatively low work function. In an embodiment, the second electrode 223 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof, for example. In an alternative embodiment, the second electrode 223 may further include a layer such as ITO, IZO, ZnO, or In₂O₃ over the (semi) transparent layer including the above material.

The emission layer 222b may be formed over the display area DA to overlap the first electrode 221 through the opening of the bank layer 215. The first functional layer 222a, the second functional layer 222c, and the second electrode 223 may cover an entirety of the display area DA.

A spacer 217 may be formed over the bank layer 215. The spacer 217 and the bank layer 215 may be formed together in the same process or may be separately formed in separate processes. In an embodiment, the spacer 217 may include an organic insulating material such as polyimide. In an alternative embodiment, the bank layer 215 may include an organic insulating material including a light-blocking dye, and the spacer 217 may include an organic insulating material such as polyimide.

The organic light-emitting diode OLED may be covered by an encapsulation layer 300. The encapsulation layer 300 may include at least one organic encapsulation layer and at least one inorganic encapsulation layer. In an embodiment, FIG. 11 illustrates that the encapsulation layer 300 includes first and second inorganic encapsulation layers 310 and 330 and an organic encapsulation layer 320 arranged therebetween.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may include a single-layer or multiple layers including the above material. The organic encapsulation layer 320 may include a polymer-based material. The polymer-based material may include acryl-based resin, epoxy-based resin, polyimide, polyethylene, or the like. In an embodiment, the organic encapsulation layer 320 may include acrylate.

The thicknesses of the first inorganic encapsulation layer 310 and the second inorganic encapsulation layer 330 may be different from each other. The thickness of the first inorganic encapsulation layer 310 may be greater than the thickness of the second inorganic encapsulation layer 330. In an alternative embodiment, the thickness of the second inorganic encapsulation layer 330 may be greater than the thickness of the first inorganic encapsulation layer 310, or the thicknesses of the first inorganic encapsulation layer 310 and the second inorganic encapsulation layer 330 may be equal to each other.

An input sensing layer 400 may be disposed over the encapsulation layer 300. The input sensing layer 400 may include touch electrodes TE arranged in the display area DA, and at least one touch insulating layer. In this regard, FIG. 11 illustrates that the input sensing layer 400 includes a first touch insulating layer 410 over the second inorganic encapsulation layer 330, a first conductive line 420 over the first touch insulating layer 410, a second touch insulating layer 430 over the first conductive line 420, a second conductive line 440 over the second touch insulating layer 430, and a third touch insulating layer 450 over the second conductive line 440.

Each of the first touch insulating layer 410, the second touch insulating layer 430, and the third touch insulating layer 450 may include an inorganic insulating material and/or an organic insulating material. In an embodiment, the first touch insulating layer 410 and the second touch insulating layer 430 may include an inorganic insulating material such as silicon oxide, silicon nitride, and/or silicon oxynitride, and the third touch insulating layer 450 may include an organic insulating material.

The touch electrode TE of the input sensing layer 400 may include a structure in which the first conductive line 420 and the second conductive line 440 are connected to each other. In an alternative embodiment, the touch electrode TE may include any one of the first conductive line 420 and the second conductive line 440, and in this case, the second touch insulating layer 430 may be omitted.

Each of the first conductive line 420 and the second conductive line 440 may include aluminum (Al), copper (Cu), and/or titanium (Ti) and may include a single layer or multiple layers including the above material. In an embodiment, each of the first conductive line 420 and the second conductive line 440 may have a three-layer structure of titanium layer/aluminum layer/titanium layer, for example.

The electronic apparatus manufacturing apparatus and the electronic apparatus manufacturing method in embodiments may control the vibration of the device, on which the electronic apparatus manufacturing process is performed, due to the vibration that occurs when the process product moves.

The electronic apparatus manufacturing apparatus and the electronic apparatus manufacturing method in embodiments may increase the lifetime thereof by reducing the malfunction of the device on which the electronic apparatus manufacturing process is performed.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

1. An apparatus which manufactures an electronic apparatus including a display panel, the apparatus comprising:
at least two transporters which transport process products;
a processor which performs a manufacturing process on a process product transported by at least one of the at least two transporters;
a processor measurer disposed on the processor and measures a processor vibration of the processor; and
a controller which calculates a processor frequency response of the processor based on the processor vibration and adjusts a velocity and a position of each of the at least two transporters or a number of transporters arranged in one area among the at least two transporters based on the processor frequency response.

2. The apparatus of claim 1, wherein the controller reduces a velocity of at least one of the at least two transporters when the processor frequency response is determined to be greater than a preset frequency response.

3. The apparatus of claim 1, wherein the controller reduces a velocity of a transporter with a highest velocity among the at least two transporters before a velocity of remaining transporters among the at least two transporters when the processor frequency response is greater than a preset frequency response.

4. The apparatus of claim 1, wherein the controller increases a velocity of at least one of the at least two transporters when the processor frequency response is determined to be less than a preset frequency response.

5. The apparatus of claim 1, wherein the controller changes a path of at least one of the at least two transporters into a path different from an existing path when the processor frequency response is greater than a preset frequency response.

6. The apparatus of claim 1, wherein the controller determines a process schedule including a velocity and a movement path of the at least two transporters based on a transporter vibration and the processor vibration measured by the processor measurer while one of the at least two transporters moves.

7. The apparatus of claim 1, further comprising a transporter measurer which is disposed on each of the at least two transporters and measures a transporter vibration of the transporter,
wherein the controller calculates a transporter frequency response of each of the at least two transporters based on the transporter vibration and calculates an impulse response of the processor according to a transporter vibration of one of the at least two transporters based on the transporter frequency response and the processor frequency response.

8. The apparatus of claim 7, wherein the controller controls a velocity of at least one of the at least two transporters based on the impulse response.

9. A method for manufacturing an electronic apparatus including a display panel, the method comprising:
measuring a processor vibration of a processor which occurs in the processor when at least two transporters move;
calculating a processor frequency response based on the processor vibration; and
adjusting a velocity and a position of each of the at least two transporters or a number of transporters arranged in one area among the at least two transporters based on the processor frequency response.

10. The method of claim 9, further comprising comparing the processor frequency response with a preset frequency response.

11. The method of claim 10, further comprising reducing a velocity of at least one of the at least two transporters when the processor frequency response is determined to be greater than the preset frequency response.

12. The method of claim 10, further comprising reducing a velocity of a transporter with a highest velocity among the at least two transporters before a velocity of remaining transporters among the at least two transporters when the processor frequency response is greater than the preset frequency response.

13. The method of claim 10, further comprising increasing a velocity of at least one of the at least two transporters when the processor frequency response is determined to be less than the preset frequency response.

14. The method of claim 10, further comprising changing a path of at least one of the at least two transporters into a path different from an existing path when the processor frequency response is greater than or equal to the preset frequency response.

15. The method of claim 9, further comprising measuring a transporter vibration of the transporter which occurs according to a movement of the at least two transporters.

16. The method of claim 15, further comprising determining a process schedule including a velocity and a movement path of the at least two transporters based on the transporter vibration and the processor vibration while one of the at least two transporters moves.

17. The method of claim 15, further comprising calculating a transporter frequency response of each of the at least two transporters based on the transporter vibration.

18. The method of claim 17, further comprising calculating an impulse response of the processor according to the transporter vibration of one of the at least two transporters based on the transporter frequency response and the processor frequency response.

19. The method of claim 18, wherein a velocity of one of the at least two transporters is controlled based on the impulse response.

20. The method of claim 19, wherein a velocity of one of the at least two transporters with a greatest impulse response of the processor according to the transporter vibration is more variable than a velocity of remaining transporters among the at least two transporters.
